(19) United States
(12) Patent Application Publication
(10) Pub. No.: US 2026/0289035 A1
(43) Pub. Date: Sep. 24, 2026

(54) SYSTEM

(71) Applicant: SoftBank Group Corp., Tokyo (JP)

(72) Inventor: Teppei TAKAHASHI, Tokyo (JP)

(73) Assignee: SoftBank Group Corp., Tokyo (JP)

(21) Appl. No.: 19/567,032

(22) Filed: Mar. 14, 2026

(30) Foreign Application Priority Data
Mar. 19, 2025 (JP) 2025-045224

(51) Int. Cl. G06F 30/17; G06F 30/27

(52) U.S. Cl. CPC G06F 30/17; G06F 30/27

(57) ABSTRACT

A system includes a processor that is configured to learn design information, specification information, and configuration information of commercial equipment by fine-tuning, based on a large language model having performance comparable to a generative artificial intelligence model, predict an impact range at the time of occurrence of an accident, propose an optimal recovery procedure based on patterns learned from past data, analyze an emotional state of a user, and adjust operation of the system based on a result of the emotional analysis.

### CROSS-REFERENCE TO RELATED APPLICATION

This application is based on and claims priority under 35 USC 119 from Japanese Patent Application No. 2025-045224 filed on Mar. 19, 2025, the disclosure of which is incorporated by reference herein.

### BACKGROUND

### Technical Field

The present disclosure relates to a system.

### Related Art

Japanese Patent Application Laid-Open (JP-A) No. 2022-180282 discloses a persona chatbot control method executed by at least one processor. The method includes steps of: receiving a user utterance, adding the user utterance to a prompt including a description of a chatbot character and an associated instruction sentence, encoding the prompt, and inputting the encoded prompt to a language model to generate a chatbot utterance responding to the user utterance.

Conventional systems for managing commercial equipment, including design, operation, and maintenance support systems, generally rely on static documents, rule-based engines, and manually defined workflows. Such systems are not capable of dynamically learning complex relationships among design information, specification information, and configuration information of commercial equipment. As a result, when an accident occurs, conventional systems often fail to accurately predict an impact range of the accident and cannot promptly propose an optimal recovery procedure that reflects both historical accident patterns and current operating conditions.

Furthermore, conventional systems typically do not analyze a psychological or emotional state of a user who operates the system in an emergency situation. Under high-stress conditions, a user may misinterpret system outputs, overlook critical information, or make suboptimal decisions. Existing systems generally provide uniform responses regardless of the user's emotional state, and therefore cannot adapt the interaction style or guidance level to the user's condition. This may lead to delays in recovery, increased risk of human error, and reduced overall safety and reliability of the commercial equipment.

Accordingly, there is a need for a system that utilizes a large language model with capability comparable to a generative artificial intelligence model, to learn design, specification, and configuration information of commercial equipment through fine-tuning, to predict an impact range at the time of an accident and propose an optimal recovery procedure based on patterns learned from past data, and further to analyze a user's emotional state and adjust system behavior based on an emotional analysis result. Such a system is required to improve responsiveness, accuracy, and usability in accident response and recovery operations.

### SUMMARY

To solve the above-described problems, a system according to at least one embodiment of the present invention comprises a processor, wherein the processor is configured to learn design information, specification information, and configuration information of commercial equipment by fine-tuning, based on a large language model having performance comparable to a generative artificial intelligence model. By performing fine-tuning with design information, specification information, and configuration information as training data, the processor internalizes detailed knowledge about structures, functions, dependencies, and constraints of the commercial equipment, and thus can generate context-aware outputs in response to accident-related inputs.

The processor is further configured to predict an impact range at a time of occurrence of an accident and to propose an optimal recovery procedure based on patterns learned from past data. In particular, the processor may use a generative AI model to analyze past accident data, extract characteristic patterns regarding propagation of failures and effectiveness of recovery actions, and estimate an impact of a current accident by comparing the current situation with the learned patterns. Based on the estimated impact, the processor can generate a recovery procedure that considers safety requirements, system dependencies, and priority of restoration targets, thereby supporting rapid and effective recovery.

Moreover, the processor is configured to analyze an emotional state of a user and adjust operation of the system based on a result of emotional analysis. For example, the processor may analyze a user's text input, voice input, or interaction behavior by using a generative AI model or an auxiliary model to estimate emotional states such as anxiety, confusion, or calmness. In accordance with the estimated emotional state, the processor may modify the level of detail of explanations, the degree of guidance, the interaction speed, or the presentation format of information. By dynamically adapting system behavior to the user's emotional state, the system can reduce cognitive load on the user, lower the possibility of human error, and enhance reliability and safety in accident response and recovery operations.

The term “system” refers to a combination of hardware and software components, including at least one processor and associated memory and interfaces, that cooperatively execute functions described in the present specification and claims.

The term “processor” refers to any hardware device or combination of hardware devices capable of executing instructions, including but not limited to a central processing unit (CPU), a graphics processing unit (GPU), a digital signal processor (DSP), a microcontroller, or a programmable logic device, as well as a plurality of such devices operating in cooperation.

The term “large language model” refers to a machine learning model trained on a large corpus of text data and configured to perform natural language understanding and generation, typically including a neural network with a large number of parameters capable of producing context-aware textual outputs.

The term “generative artificial intelligence model” refers to an artificial intelligence model configured to generate new data, such as text, images, or other content, based on learned patterns from training data, including but not limited to generative large language models. The term “design information” refers to information describing the structure, architecture, and functional configuration of commercial equipment, including but not limited to system diagrams, block diagrams, component layouts, control logic, and related engineering specifications.

The term “specification information” refers to information defining technical specifications and operating parameters of commercial equipment, including but not limited to ratings, tolerances, performance characteristics, environmental conditions, and operational constraints.

The term “configuration information” refers to information indicating how commercial equipment is arranged, interconnected, and parameterized in an actual or planned installation, including but not limited to network settings, parameter sets, hardware and software versions, and inter-device relationships.

The term “commercial equipment” refers to equipment, systems, or installations used in industrial, commercial, or business environments, including but not limited to manufacturing machinery, plant equipment, infrastructure systems, and associated control systems. The term “fine-tuning” refers to a process of additional training of a pre-trained model, such as a large language model, on domain-specific data so as to adapt the model's parameters and behavior to a particular application area or dataset.

The term “impact range” refers to a scope or extent of influence caused by an accident in commercial equipment, including affected devices, subsystems, processes, services, or customers, and any associated degradation of performance or safety.

The term “recovery procedure” refers to an ordered set of actions or steps to be executed after occurrence of an accident in commercial equipment, the actions being intended to restore normal or acceptable operation while maintaining safety and compliance with system constraints.

The term “past data” refers to historical information stored prior to evaluation of a current situation, including but not limited to past accident records, operation logs, maintenance logs, and prior recovery procedures and their outcomes.

The term “past accident data” refers to a subset of past data that specifically relates to previously occurred accidents, failures, abnormal events, and associated conditions, including causes, impact ranges, countermeasures, and recovery results.

The term “user” refers to a human operator, engineer, maintenance personnel, supervisor, or other person who interacts with the system to monitor, control, or analyze commercial equipment or accidents.

The term “emotional state” refers to a psychological or affective condition of a user, such as anxiety, stress, confusion, calmness, confidence, or frustration, inferred from user inputs or behaviors.

The term “emotional analysis” refers to a process of estimating or classifying a user's emotional state by analyzing user inputs, including text, voice, or interaction patterns, using artificial intelligence techniques or other computational methods.

The term “adjust operation of the system” refers to modifying one or more aspects of system behavior, including but not limited to content, level of detail, interaction style, timing, or format of outputs, based on internal processing results such as emotional analysis.

### BRIEF DESCRIPTION OF THE DRAWINGS

Exemplary embodiments of the present disclosure will be described in detail based on the following figures, wherein:

FIG. 1 is a schematic diagram illustrating an example of a configuration of a data processing system according to a first exemplary embodiment;

FIG. 2 is a schematic diagram illustrating an example of relevant functions of a data processing device and a smart device according to the first exemplary embodiment;

FIG. 3 is a schematic diagram illustrating an example of a configuration of a data processing system according to a second exemplary embodiment;

FIG. 4 is a schematic diagram illustrating an example of relevant functions of a data processing device and smart glasses according to the second exemplary embodiment;

FIG. 5 is a schematic diagram illustrating an example of a configuration of a data processing system according to a third exemplary embodiment;

FIG. 6 is a schematic diagram illustrating an example of relevant functions of a data processing device and a headset-type terminal according to the third exemplary embodiment;

FIG. 7 is a schematic diagram illustrating an example of a configuration of a data processing system according to a fourth exemplary embodiment;

FIG. 8 is a schematic diagram illustrating an example of relevant functions of a data processing device and a robot according to the fourth exemplary embodiment;

FIG. 9 illustrates an emotion map mapping plural emotions;

FIG. 10 illustrates an emotion map mapping plural emotions;

FIG. 11 is a sequence diagram showing the flow of data processing system processing in Example 1;

FIG. 12 is a sequence diagram showing the flow of data processing system processing in Application Example 1;

FIG. 13 is a sequence diagram showing the flow of data processing system processing in Example 2; and

FIG. 14 is a sequence diagram showing the flow of data processing system processing in Application Example 2.

### DETAILED DESCRIPTION

Description follows regarding an example of exemplary embodiments of a system according to technology disclosed herein, with reference to the appended drawings.

First, explanation follows regarding terminology employed in the following description.

In the following exemplary embodiments, a reference-numeral-appended processor (hereinafter simply referred to as “processor”) may be implemented by a single computation unit, and may be implemented by a combination of plural computation units. The processor may be implemented by a single type of computation unit, or may be implemented by a combination of plural types of computation units. Examples of computation unit include a central processing unit (CPU), a graphics processing unit (GPU), a general-purpose computing on graphics processing units (GPGPU), an accelerated processing unit (APU), and the like.

In the following exemplary embodiments, random access memory (RAM) appended with a reference numeral is memory temporarily stored with information, and is employed as working memory by a processor.

In the following exemplary embodiments, reference-numeral-appended storage is a single or plural non-volatile storage devices for storing various programs and various parameters and the like. Examples of non-volatile storage devices include flash memory (such as a solid state drive (SSD)), a magnetic disk (for example, a hard disk), magnetic tape, and the like.

In the following exemplary embodiments, a reference-numeral-appended communication interface (I/F) is an interface including a communication processor and an antenna or the like. The communication I/F has the role of communicating between plural computers. An example of a communication standard applied for the communication I/F is a wireless communication standard, such as a Fifth Generation Mobile Communication System (5G), Wi-Fi (registered trademark), Bluetooth (registered trademark), and the like.

In the following exemplary embodiments “A and/or B” has the same definition as “at least one out of A or B”. Namely, “A and/or B” may mean A alone, may mean B alone, or may mean a combination of A and B. Moreover, similar logic to “A and/or B” is applied when “and/or” is employed to link three or more items in the present specification.

### First Exemplary Embodiment

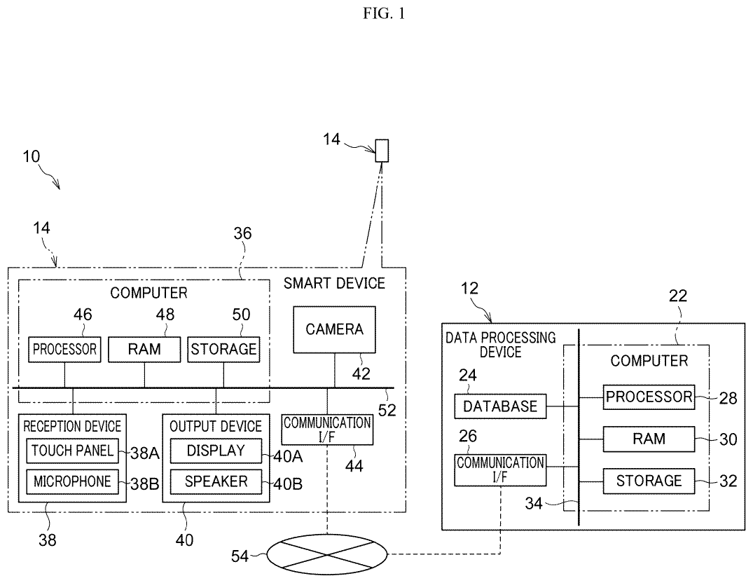

FIG. 1 illustrates an example of a configuration of a data processing system 10 according to a first exemplary embodiment.

As illustrated in FIG. 1, the data processing system 10 includes a data processing device 12 and a smart device 14. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The smart device 14 includes a computer 36, a reception device 38, an output device 40, a camera 42, and a communication I/F 44. The computer 36 includes a processor 46, RAM 48, and storage 50. The processor 46, the RAM 48, and the storage 50 are connected to a bus 52. The reception device 38, the output device 40, the camera 42, and the communication I/F 44 are also connected to the bus 52.

The reception device 38 includes a touch panel 38A, a microphone 38B, and the like for receiving user input. The touch panel 38A receives user input from contact of a pointer (for example, a pen, a finger, or the like) by detecting contact of the pointer. The microphone 38B receives spoken user input by detecting speech of the user. A control unit 46A in the processor 46 transmits data representing the user input received by the touch panel 38A and the microphone 38B to the data processing device 12. A specific processing unit 290 in the data processing device 12 acquires the data indicating the user input.

The output device 40 includes a display 40A, a speaker 40B, and the like for presenting data to a user 20 by outputting the data in an expression format perceivable by the user 20 (for example, audio and/or text). The display 40A displays visual information such as text, images, or the like under instruction from the processor 46. The speaker 40B outputs audio under instruction from the processor 46. The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like.

The communication I/F 44 is connected to the network 54. The communication I/F 44 and the communication I/F 26 perform the role of exchanging various information between the processor 46 and the processor 28 over the network 54.

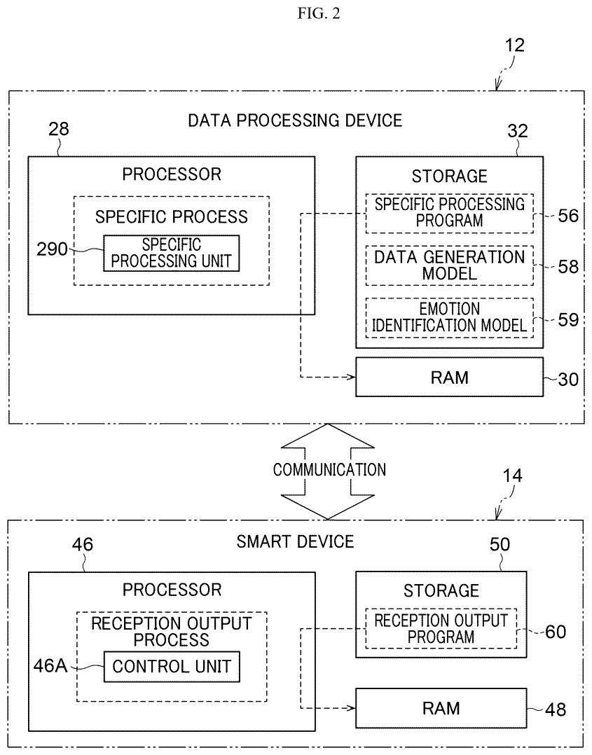

FIG. 2 illustrates an example of relevant functions of the data processing device 12 and the smart device 14.

As illustrated in FIG. 2, specific processing is performed by the processor 28 in the data processing device 12. A specific processing program 56 is stored in the storage 32. The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

A data generation model 58 and an emotion identification model 59 are stored in the storage 32. The data generation model 58 and the emotion identification model 59 are employed by the specific processing unit 290. The specific processing unit 290 uses the emotion identification model 59 to estimate an emotion of a user, and is able to perform the specific processing using the user emotion. In an emotion estimation function (emotion identification function) that uses the emotion identification model 59, various estimations, predictions, and the like are performed related to emotions of the user, include estimating and predicting the emotion of the user, however, there is no limitation to such examples. Moreover, estimation and prediction of emotion also includes, for example, analyzing (parsing) emotions and the like.

Reception and output processing is performed by the processor 46 in the smart device 14. A reception and output program 60 is stored in the storage 50. The reception and output program 60 is employed by the data processing system 10 in combination with the specific processing program 56. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48. Note that a configuration may be adopted in which a similar data generation model and emotion identification model to the data generation model 58 and the emotion identification model 59 are included in the smart device 14, and these models are used to perform similar processing to the specific processing unit 290. The reception and output program is implemented by the processor 46 operating as the control unit 46A according to the reception and output program 60 executed in the RAM 48.

Note that devices other than the data processing device 12 may include the data generation model 58. For example, a server device (for example, a generation server) may include the data generation model 58. In such cases, the data processing device 12 performs communication with the server device including the data generation model 58 to obtain a processing result (prediction result or the like) obtained using the data generation model 58. The data processing device 12 may be a server device, and may be a terminal device owned by the user (for example, a mobile phone, a robot, a home electrical appliance, or the like). Next, description follows regarding an example of processing by the data processing system 10 according to the first exemplary embodiment.

### Example 1

Description follows regarding a flow of the specific processing in an Example 1. The units of the system described below are implemented by the data processing device 12 and the smart device 14. The data processing device 12 is called a “server” and the smart device 14 is called a “terminal”.

Conventional computer-implemented support systems for design and operation of industrial facilities rely on manually engineered rules, fixed templates, or keyword-based search across static documents. Such systems typically treat design documents, specification documents, and configuration data as unstructured text or files that are retrieved and displayed as-is. As a result, existing systems do not construct a unified, machine-interpretable internal representation of facility knowledge, and are therefore limited in their ability to generate adaptive responses for complex operational scenarios, such as prediction of impact ranges at the time of an incident and automated proposal of recovery procedures. In addition, conventional systems that employ machine learning models often require task-specific models that are trained from scratch on narrow data sets. This leads to high development and maintenance costs and makes it difficult to continually incorporate newly provided design and specification information. Even when a large-scale language model is used, existing approaches frequently apply the model in a generic manner without domain-specific fine-tuning based on the latest facility documents, resulting in responses that are incomplete, inconsistent with the actual configuration, or not directly actionable in incident situations.

Furthermore, conventional incident response tools generally separate document management from inference engines. In many architectures, text preprocessing, model training, context retrieval, and response generation are handled as loosely connected modules, without an integrated pipeline that systematically transforms raw electronic documents into preprocessed learning data, domain-specific model parameters, and context-conditioned inference inputs. This fragmented architecture introduces latency, increases resource consumption, and complicates reproducibility and traceability of model behavior.

Moreover, existing systems typically lack a mechanism by which a processor can dynamically select, from preprocessed domain text, context information relevant to a user's prompt sentence and encode that context jointly with the prompt into a form suitable for inference by a fine-tuned generative model. Without such tight integration of prompt, context selection, and domain-specific internal representations, the system cannot effectively exploit the full capacity of a large-scale generative model to output accurate predictions of incident impact ranges or to synthesize stepwise recovery procedures.

Accordingly, there is a need for an improved computer-implemented technique that transforms heterogeneous electronic facility documents into structured learning data, fine-tunes a generative AI model to form a domain-specific internal representation, and, at runtime, accepts user prompt sentences, automatically assembles relevant context from the preprocessed domain corpus, and performs efficient inference to produce incident-aware, procedure-oriented responses. Such an improvement should provide better utilization of computing resources, reduced response time, and improved correctness and specificity of generated outputs compared to conventional systems.

The specific processing by the specific processing unit 290 of the data processing device 12 in Example 1 is realized by the following means.

The present invention provides a server comprising a processor configured to receive electronic document data from an information terminal, to extract design-related information, specification-related information, and configuration-related information from the electronic document data, to perform natural language preprocessing including at least sentence segmentation, word segmentation, removal of non-informative content, and attachment of structural annotations so as to generate learning data, to fine-tune a generative AI model based on a large-scale language model using the learning data so as to form a domain-specific model that acquires internal representations of the design-related information, the specification-related information, and the configuration-related information regarding industrial equipment, to receive inquiry information including a prompt sentence from the information terminal, to select, as context information, preprocessed information relevant to the inquiry information, to generate input data for inference by combining the prompt sentence with the context information, to execute inference processing by the domain-specific model based on the input data so as to generate response information including a prediction result of an impact range at occurrence of an incident and a recovery procedure based on patterns learned from the learning data, and to transmit the response information to the information terminal for display. This enables an integrated computer-implemented pipeline that converts heterogeneous facility documents into model-usable representations, optimizes a generative AI model for a specific industrial domain, and dynamically conditions inference on user prompts and automatically selected context, thereby improving computational efficiency, response latency, and the technical accuracy and actionable quality of incident prediction and recovery guidance generated by the server.

The term “electronic document data” refers to digital data representing one or more documents, including but not limited to files in a text, image, or mixed-media format, that describe design, specification, or configuration information for a physical system. The term “information terminal” refers to an electronic device operated by a user, such as a workstation, a portable computing device, or a network-connected display device, that is configured to transmit data to and receive data from a server over a communication network. The term “design-related information” refers to information contained in an electronic document that describes structural, functional, or layout aspects of a physical system, including, for example, component arrangements, system architecture, and design parameters.

The term “specification-related information” refers to information contained in an electronic document that describes performance conditions, operating constraints, or functional requirements of a physical system, including, for example, rated capacities, tolerances, and operating procedures.

The term “configuration-related information” refers to information contained in an electronic document that describes relationships among components of a physical system, including, for example, interconnections, dependencies, and deployment settings.

The term “natural language processing algorithm” refers to a computational procedure that operates on human-readable text to perform at least one of tokenization, segmentation, morphological analysis, syntactic analysis, or semantic analysis.

The term “preprocessing” refers to a sequence of operations applied to raw text data, including at least sentence segmentation, word segmentation, removal of non-informative content, and attachment of structural annotations, to transform the raw text into a structured form suitable for machine learning.

The term “sentence segmentation” refers to an operation that divides a text sequence into units corresponding to sentences or similar linguistic segments.

The term “word segmentation” refers to an operation that divides a text sequence into units corresponding to words, tokens, or subword elements usable by a language model. The term “non-informative content” refers to portions of text that are not relevant to the intended learning or inference task, including but not limited to boilerplate text, disclaimers, headers, footers, and formatting artifacts.

The term “structural annotations” refers to metadata associated with text, indicating at least one of document sections, headings, lists, tables, or semantic labels, which facilitates downstream processing or learning.

The term “learning data” refers to structured data generated from preprocessed information that is formatted for use as input to a machine learning algorithm, including input sequences, target sequences, and associated labels.

The term “large-scale language model” refers to a parametric model that has been trained on a large corpus of natural language text and that is configured to perform at least one of natural language understanding, natural language generation, or language modeling.

The term “generative AI model” refers to a machine learning model that is configured to generate output data, such as natural language text, based on input data, and that includes a large-scale language model or a model derived therefrom.

The term “fine-tune” refers to a process of performing additional training of a previously trained model on task-specific or domain-specific learning data, thereby adapting model parameters to a particular use case.

The term “domain-specific model” refers to a generative AI model that has been fine-tuned using learning data related to a particular technical or operational domain, such that the model encodes internal representations tailored to that domain.

The term “internal representations” refers to numerical or symbolic encodings within a model that capture semantic, syntactic, or structural properties of input data, and that are used by the model to perform inference or generation.

The term “industrial equipment” refers to machinery, apparatus, or systems used in a production, processing, or commercial facility, including their associated components and subsystems.

The term “inquiry information” refers to data received from an information terminal that includes at least one prompt sentence and optionally additional metadata, and that specifies a user's request for processing or information.

The term “prompt sentence” refers to a natural language expression provided by a user as an instruction, query, or request that guides the behavior or output of a generative AI model. The term “context information” refers to preprocessed information selected from a corpus based on its relevance to inquiry information, and combined with a prompt sentence to form input data for a model.

The term “input data” refers to data provided to a model for performing inference, including at least a representation of a prompt sentence and associated context information.

The term “inference processing” refers to computation performed by a trained model in which model parameters are applied to input data to generate output data without updating the model parameters.

The term “response information” refers to data generated by the domain-specific model in response to input data, including at least textual content such as explanations, predictions, or procedure descriptions.

The term “impact range” refers to a scope or extent of consequence on components, subsystems, or operations of a physical system caused by an incident or abnormal event. The term “incident” refers to an unplanned event or abnormal condition, including failure, malfunction, or disruption, that affects at least part of an industrial system.

The term “recovery procedure” refers to a sequence of operations, steps, or actions that are to be executed for restoring a system or subsystem from an incident state to a normal or acceptable state.

The term “patterns learned from the learning data” refers to statistical or structural regularities captured by the model during training, which relate input conditions to output behaviors, including correlations among configurations, incidents, and recovery actions. The term “token sequence” refers to an ordered list of discrete symbols, identifiers, or indices produced by a tokenizer from text, and used as input to or output from a language model. The term “weight parameters” refers to numerical values within a model that determine the contribution of inputs and intermediate representations to outputs and that are updated during training or fine-tuning.

The term “feature patterns extracted from data regarding past incidents” refers to characteristic relationships or signatures derived from historical incident data, including co-occurring events, temporal profiles, or configuration-dependent effects, which are used for estimating current impact ranges.

In one embodiment, a server, a terminal, and a user cooperate to implement the claimed system. The server includes at least one processor, a memory, a non-volatile storage device, a network interface, and, in some embodiments, a hardware accelerator such as a graphics processing unit. The terminal includes a processor, a display, an input interface, and a network interface, and is connected to the server via a communication network such as an IP network.

The server executes a software stack comprising an operating system, a web server component, an application server component, a database management component, and a machine-learning framework. The server uses widely available software components, such as an operating system of a server class, a web server framework, an application framework, a relational or non-relational database system, and a machine-learning framework capable of executing a neural network. The server further uses natural language processing libraries, such as a sentence and token segmentation toolkit and a linguistic analysis toolkit, to implement natural language processing algorithms.

The terminal executes a client application, such as a browser-based interface or a dedicated application, that allows the user to upload electronic document data and to input a prompt sentence. The terminal displays interface elements such as file selection controls, text entry fields, and response display regions. The terminal transmits data to and receives data from the server using a network protocol.

The user operates the terminal to select electronic document data representing design-related information, specification-related information, and configuration-related information of industrial equipment. The terminal transmits these electronic document data to the server via the network interface. The server stores the received electronic document data on the non-volatile storage device in association with metadata such as equipment identifiers, document types, and timestamps.

The server uses a document parsing module, implemented using a document processing library, to convert the electronic document data into machine-readable text. For example, when the electronic document data is in a portable document format, the server extracts text content and document structure from each page. When the electronic document data is in a word processing format, the server extracts paragraphs, headings, lists, and tables. The server normalizes character encodings and converts heterogeneous document formats into a common internal representation.

The server applies natural language processing algorithms to the extracted text. The server performs sentence segmentation by detecting punctuation and linguistic cues to divide the text into sentence units. The server performs word segmentation by applying a tokenizer that splits each sentence into tokens corresponding to words or subword units compatible with a generative AI model. The server removes non-informative content such as boilerplate headers, legal disclaimers, page numbers, and repeated footers using rule-based filters and pattern matching. The server attaches structural annotations indicating section types (for example, design overview, performance specifications, safety instructions), heading hierarchy, table structure, and cross-references between components.

The server stores the preprocessed text in a database using a structured data model. In one embodiment, the server stores each document as a collection of records, where each record includes tokenized text, sentence boundaries, structural annotations, and references to the original document location. The server further stores index structures, such as an inverted index or vector index, that map terms or embeddings to document segments, thereby enabling efficient retrieval of context information relevant to a prompt sentence.

The server constructs learning data for a generative AI model using the preprocessed text. The server generates training examples by pairing instructions and responses derived from the structure of the documents. For example, the server uses a document heading or a design requirement statement as an instruction and uses the corresponding explanatory paragraphs as a response. The server also defines patterns for incident-related training data by pairing incident descriptions with impact ranges and recovery procedures extracted from historical incident records and operating manuals if such data are available. The server formats each training example with fields such as an instruction, context text, and target text.

The server encodes the learning data using a tokenizer associated with a large-scale language model. The server converts each instruction, context text, and target text into sequences of token identifiers. The server concatenates these sequences with special boundary tokens to form an input-output pair suitable for supervised learning. The server enforces a maximum sequence length by truncating less relevant portions or by splitting overly long examples into multiple samples. The server stores the resulting token sequences in an efficient binary format on the storage device to support high-throughput loading during training.

The server initializes a generative AI model based on a large-scale language model, such as a transformer-based neural network having multiple self-attention layers, feedforward layers, layer normalization, and residual connections. The server configures the network architecture with a vocabulary size, a number of layers, a hidden dimension size, and attention head counts appropriate for the target domain. The server loads pretrained weight parameters obtained from prior training on a general natural language corpus.

The server fine-tunes the generative AI model using the learning data. The server uses a machine-learning framework to implement a training procedure that includes forward propagation, loss computation, backward propagation, and weight updates. The server defines a loss function such as cross-entropy loss between predicted token distributions and target tokens. The server uses an optimization algorithm, such as a gradient-based optimizer, to update weight parameters. The server controls hyperparameters such as learning rate, batch size, number of epochs, and gradient clipping thresholds. The server optionally applies regularization techniques such as dropout or weight decay to prevent overfitting. The server executes the training loops on a hardware accelerator, thereby improving training speed and enabling the use of larger models and datasets. The server monitors training metrics such as training loss and validation loss, and performs checkpointing of model parameters to the storage device. The server selects a checkpoint that yields a desirable balance between generalization performance and domain specificity as a domain-specific model.

The server thus transforms the generative AI model into a domain-specific model whose internal representations capture correlations between design-related information, specification-related information, configuration-related information, and incident outcomes. Because the server fine-tunes the model on structured, preprocessed data rather than raw text, the server reduces noise and improves model convergence, which in turn improves prediction accuracy and response quality. This results in a technical improvement over naïve application of a generic language model.

The user later operates the terminal to input a prompt sentence requesting analysis or design support. For example, the user may input:

“Based on the uploaded design document of the compressor system, propose a recovery procedure in case of a main compressor shutdown.” or

“Based on the uploaded filling line design and specification documents, propose an optimal equipment arrangement that minimizes downtime caused by a failure of the main conveyor, and describe the recovery steps.” or

“Using the specification document for the refrigeration system, estimate the impact range if the main compressor fails and list the recovery steps.”

The terminal transmits the prompt sentence and an identifier of the relevant equipment or documents to the server. The server receives the inquiry information, including the prompt sentence, and uses the identifier to select candidate document segments from the preprocessed text stored in the database. The server applies a retrieval algorithm, such as keyword-based search, term frequency-based ranking, or vector similarity search based on embeddings, to identify document segments that are most relevant to the prompt sentence. The server thus obtains context information that captures constraints, configurations, and operational conditions associated with the subject equipment.

The server converts the prompt sentence and the selected context information into token sequences using the tokenizer associated with the domain-specific model. The server concatenates the token sequence representing the prompt sentence with token sequences representing the context information, separated by special tokens that mark segment boundaries. The server generates input data that explicitly encodes both user instructions and domain context, thereby enabling the model to condition its generation on specific equipment characteristics and operational constraints

The server executes inference processing of the domain-specific model using the generated input data. The server disables gradient computation and processes the input token sequence through the transformer layers to compute a sequence of hidden states. The server applies a decoding algorithm, such as greedy decoding, beam search, top-k sampling, or nucleus sampling, to generate output token sequences that maximize a conditional probability given the input data. The server enforces constraints on sequence length and uses stopping criteria based on special end-of-sequence tokens. The server converts the output token sequences into natural language text as response information.

Because the server employs a domain-specific model trained on structured design-related information, specification-related information, and configuration-related information, the server can generate response information that includes a prediction of incident impact ranges and a recovery procedure specific to the configuration. The response information is not limited to generic instructions; rather, it reflects dependencies between equipment elements and considers operational constraints, such as safety zones and capacity limits, that are encoded in the internal representations of the model.

The server transmits the response information to the terminal. The terminal displays the response information in a human-readable form, such as a structured text containing headings, bullet lists, or numbered steps. For example, the response information may include a stepwise recovery procedure describing isolation of a failed compressor, re-routing of material flows, or staged restart sequences. The terminal may further allow the user to request refinements by submitting additional prompt sentences, thereby iteratively converging on a configuration or procedure that is practically implementable.

The server thus performs more than simple automation of human reading and drafting of procedures. The server implements a specific data flow and model-adaptation mechanism that improves computer operation. The server reduces the size of the effective input space by eliminating non-informative content and by aligning document structure with training examples, which improves convergence speed and reduces computational cost during training. The server further improves inference efficiency by selecting only context information relevant to a prompt sentence, thereby reducing the number of tokens processed by the model and decreasing latency. These effects constitute improvements in the functioning of the computer system itself, as they enhance resource utilization and performance of the model across heterogeneous document sets.

The server also implements a consistent internal representation of the domain in the form of tokenized, annotated text and learned neural network parameters. This representation enables the server to perform pattern-based inference that is not achievable by a human operator or by a simple rules engine within practical time limits. For example, the server can systematically consider large numbers of possible failure modes and configuration states encoded in the training data, and derive impact ranges and recovery procedures by propagating effects through the learned attention patterns of the transformer layers. This results in more accurate and consistent outputs compared to ad hoc manual analysis.

In another embodiment, the server uses alternative architectures and training methods while preserving the same technical concept. The server may use an encoder-decoder architecture rather than a decoder-only transformer, or may perform multi-task learning in which document summarization and incident prediction are trained jointly. The server may also use different optimization algorithms or learning rate schedulers. The server may employ data augmentation techniques such as paraphrasing of instructions, extraction of synthetic incident scenarios from documents, or generation of contrastive negative examples, thereby improving robustness and generalization.

In another embodiment, the server deploys multiple domain-specific models targeted to different categories of industrial equipment. The server selects an appropriate model based on equipment type metadata linked to the electronic document data. The server may also maintain a shared base model and attach lightweight adaptation modules, such as low-rank adaptation layers, for specific domains, thereby reducing storage and computation requirements while maintaining specialization. This variation further improves computational efficiency and scalability.

In yet another embodiment, the server integrates the output of the domain-specific model with equipment monitoring systems. The server receives sensor values or status signals from control systems and uses such information as additional context in the prompt sentence or as separate features encoded into special tokens. The server thus generates response information that not only reflects static design and specification data, but also reflects current operating conditions. This integration allows the server to provide recommendations that are technically grounded and practically actionable, such as recommending specific setpoint adjustments or sequence modifications during recovery.

Because the server's processing is grounded in a specific architectural arrangement of preprocessing modules, data structures, and neural network inference, and because the server improves processing efficiency, model accuracy, and technical usability of the generated outputs, the system as a whole provides a concrete technological improvement over conventional document-based support tools. The system is not limited to business logic or simple information display; rather, the system enhances the capabilities of computer systems to process complex technical corpora and to generate technically valid recovery and design guidance in real time.

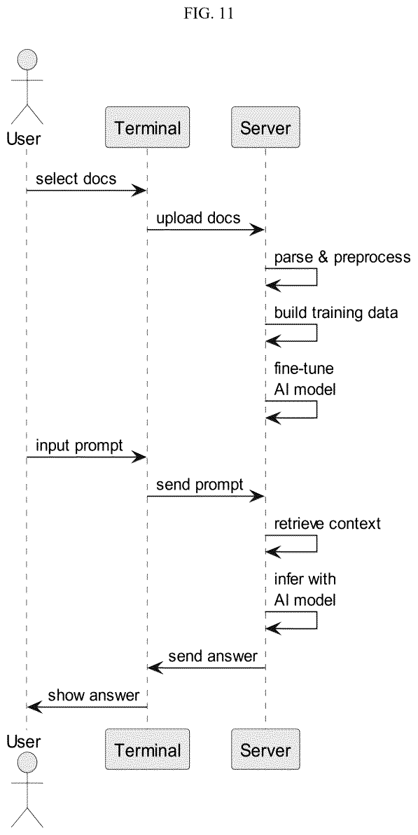

The following describes the processing flow using FIG. 11.

### Step 1

The user operates the terminal to select electronic document files that describe design, specification, and configuration information of industrial equipment.

The terminal displays a file selection interface and receives user input specifying one or more files stored in local or network storage.

Input: raw electronic document files (for example, engineering drawings in document format, specification sheets in document format, or combined text-image files).

The terminal reads basic metadata (file name, size, type) and assembles an upload request message that encapsulates the files and metadata.

The terminal transmits the upload request to the server over a network connection using a secure protocol.

Output: an upload request containing the electronic document files and metadata sent to the server.

### Step 2

The server receives the upload request from the terminal and stores the raw electronic document files in non-volatile storage.

Input: electronic document files and metadata received from the terminal.

The server validates the request, checks the file types, and assigns internal identifiers for each document and for the associated industrial equipment.

The server writes the document files to storage and records document entries in a database, including references to file locations, equipment identifiers, document categories, and timestamps.

Output: stored electronic document files and corresponding database records that reference the files and categorize the documents.

### Step 3

The server extracts text and structural information from the stored electronic document files. Input: stored document files and associated metadata from the database.

The server invokes a document parsing module to decode each document format, read page contents, and detect structural elements such as headings, paragraphs, lists, and tables. The server converts the visual or formatted content into raw character sequences and structural tags, handling embedded objects such as diagrams by extracting their captions or associated text where possible.

Output: raw text content and structural metadata for each document, stored in an intermediate data structure.

### Step 4

The server performs text preprocessing and natural language processing on the extracted content.

Input: raw text content and structural metadata obtained from the document parsing module. The server normalizes characters, unifies encodings, and removes control characters; then the server applies sentence segmentation to divide the text into sentence units.

The server applies word or subword tokenization to each sentence, producing a sequence of tokens compatible with a generative AI model.

The server removes non-informative content using rule-based filters and pattern matching, and attaches structural annotations that label tokens with section roles (for example, “design overview,” “operating condition,” “safety instruction”).

Output: preprocessed and tokenized text segments with structural annotations, stored in a database or structured files.

### Step 5

The server constructs learning data for fine-tuning a generative AI model.

Input: preprocessed text segments, structural annotations, and document metadata.

The server identifies candidate instruction segments, such as section headings, requirements statements, or incident descriptions, and associates them with corresponding explanatory or procedural segments as responses.

The server creates structured training instances that include an instruction field, a context field containing relevant background text, and a target field containing desired output text (for example, an explanation, an impact description, or a procedure).

The server stores these training instances in a structured dataset, such as a sequence of records formatted for model training.

Output: a collection of structured training instances forming learning data for the generative AI model.

### Step 6

The server encodes the learning data into token sequences suitable for neural network training.

Input: structured training instances containing instruction, context, and target text. The server applies a tokenizer associated with the base language model to each field to convert characters into token identifiers.

The server concatenates instruction, context, and target tokens using special separator tokens and inserts start and end tokens where required by the model architecture.

The server enforces a maximum sequence length by truncating or splitting instances while preserving consistency between input and target portions, and packs token sequences and attention masks into numerical arrays.

Output: tokenized training data in numerical form, ready for input to the generative AI model during fine-tuning.

### Step 7

The server fine-tunes the generative AI model using the tokenized training data.

Input: tokenized training sequences and an initialized large-scale language model with pretrained weights.

The server repeatedly loads batches of tokenized sequences into memory and performs forward passes through the neural network layers to compute predicted token distributions. The server calculates a loss value, such as cross-entropy between predicted token probabilities and target tokens, and performs backpropagation to compute gradients of the loss with respect to model weights.

The server updates the model weights using an optimization algorithm and adjusts training hyperparameters as needed, periodically evaluating the model on a validation subset to check generalization.

Output: a fine-tuned domain-specific generative AI model whose weight parameters encode internal representations of the design, specification, and configuration information.

### Step 8

The user operates the terminal to access an interaction screen and input a prompt sentence requesting analysis or support.

Input: no technical data other than user actions and any previously associated document identifiers.

The terminal displays a text input field and, optionally, a list of equipment or document identifiers for selection.

The user types a prompt sentence such as “Based on the uploaded filling line design and specification documents, propose an optimal equipment arrangement that minimizes downtime caused by a failure of the main conveyor, and describe the recovery steps.”

The terminal packages the prompt sentence together with identifiers of relevant documents or equipment and transmits this inquiry information to the server.

Output: an inquiry message containing the prompt sentence and context identifiers sent to the server.

### Step 9

The server selects context information relevant to the prompt sentence from the preprocessed corpus.

Input: the inquiry message containing the prompt sentence and document or equipment identifiers, plus the database of preprocessed and annotated text segments.

The server retrieves candidate segments linked to the specified identifiers and computes relevance scores between the prompt sentence and each segment using keyword overlap, term statistics, or vector similarity based on precomputed embeddings.

The server orders segments by relevance and selects a subset of segments that fit within a predefined token budget for the model input.

The server assembles these segments into context text in a structured format, preserving section labels and ordering to maintain logical coherence.

Output: a set of selected context segments and an aggregated context text associated with the prompt sentence.

### Step 10

The server converts the prompt sentence and selected context information into model input data.

Input: the prompt sentence and the aggregated context text from Step 9.

The server applies the model tokenizer to the prompt sentence and context text, generating token sequences and corresponding attention masks.

The server concatenates prompt and context tokens, inserting boundary tokens to distinguish user instructions from contextual background, and truncates or segments the sequence to fit within model limits while retaining high-relevance portions.

The server formats the token sequence, attention masks, and any segment identifiers into a data structure required by the generative AI model's inference interface.

Output: model input data comprising tokenized prompt and context, ready for inference.

### Step 11

The server performs inference with the fine-tuned domain-specific generative AI model. Input: model input data containing tokenized prompt and context, and the fine-tuned model parameters.

The server runs the input through the neural network in inference mode, computing successive hidden representations and output token distributions without updating weights. The server applies a decoding algorithm, such as beam search or probabilistic sampling with constraints, to iteratively select output tokens that maximize conditional likelihood while maintaining fluency and technical consistency.

The server stops generation when an end-of-sequence token is produced or when a maximum length is reached, and then converts the output token identifiers back into readable text. Output: response text that includes at least a prediction of incident impact range or an arrangement proposal and a stepwise recovery procedure corresponding to the prompt sentence.

### Step 12

The server transmits the generated response text to the terminal and optionally logs the interaction.

Input: response text produced by the generative AI model and metadata such as prompt identifiers and timestamps.

The server constructs a response message containing the generated text and any structured elements, such as numbered steps or highlighted components, and sends this message over the network to the terminal.

The server may store the request-response pair in a log repository for later analysis, model evaluation, or further training.

Output: a response message containing the generated text delivered to the terminal and a logged record stored on the server.

### Step 13

The terminal receives and displays the generated response for the user.

Input: the response message sent from the server.

The terminal parses the response message and extracts the response text and optional structured elements.

The terminal renders the response on the display, for example showing headings like “Predicted Impact Range” and “Recovery Procedure,” and formats lists or steps for readability.

The user reads the response, optionally compares it with existing procedures or designs, and may decide to refine the query by entering another prompt sentence based on the displayed result.

Output: a visual presentation of the generated analysis and procedures on the terminal display, and, optionally, a new user-generated prompt sentence initiating another iteration.

### Application Example 1

Description follows regarding a flow of the specific processing in an Application Example 1. The units of the system described below are implemented by the data processing device 12 and the smart device 14. The data processing device 12 is called a “server” and the smart device 14 is called a “terminal”.

Conventional computer systems that assist operation and maintenance of industrial equipment typically rely on static rule sets, manually authored procedures, and simple search functions over design documents and incident reports. Such systems suffer from multiple technical limitations in terms of information processing and human-machine interaction. First, conventional systems are not designed to efficiently handle large volumes of heterogeneous technical documents, including design information, specification information, and configuration information, which are often stored as long, unstructured text. As a result, when an operator or supervisory system requires context-specific work instructions or recovery procedures, the underlying computer system cannot automatically identify, extract, and combine the most relevant portions of the documents. The system therefore either returns overly broad results or requires substantial manual filtering, which leads to increased processing time, higher memory consumption due to redundant data handling, and degraded responsiveness of the information processing pipeline.

Second, known systems that incorporate machine learning or generative models generally treat technical documents as undifferentiated input, without building an efficient intermediate representation that supports fast retrieval and targeted prompt construction. In particular, these systems do not segment and structure document data with associated metadata, do not generate distributed representations (embeddings) for each segment, and do not maintain an index structure optimized for similarity search. Consequently, the systems frequently send unnecessarily large or irrelevant context to a generative model, consuming excessive computational resources, network bandwidth, and model tokens, which increases latency and cost and may cause truncation of important information.

Third, conventional systems do not provide an integrated feedback loop between field execution and the generation of instructions by a generative model. Execution status and operator feedback, if collected at all, are typically stored in logs that are not systematically analyzed to refine subsequent instructions or to adapt the model behavior. This absence of structured feedback utilization prevents the computer system from improving its instruction generation performance over time, leading to persistent inefficiencies in both normal operations and emergency response.

Fourth, in accident scenarios, traditional decision support systems are largely based on pre-defined fault trees or manually crafted recovery scripts. These systems are not capable of dynamically combining design information, specification information, configuration information, and past accident information to predict an impact range and generate optimized recovery procedures tailored to the specific incident context. As a result, the computer system cannot promptly compute incident-specific impact predictions or recovery plans, and operators must manually interpret complex documents under time pressure, which undermines the reliability and timeliness of the overall computer-implemented response. Accordingly, there is a need for an improved computer-implemented system that (i) automatically preprocesses and structures large technical document sets, (ii) constructs and exploits distributed representations and index structures for efficient retrieval, (iii) generates precise prompt sentences for a generative artificial intelligence model based on dynamically selected document segments and instruction context, and (iv) closes the loop by using structured execution status and feedback data to refine subsequent prompts and learning data. Such a system should thereby improve the technical performance of the underlying computer platform in terms of search efficiency, model input optimization, response latency, and the adaptability and accuracy of generated work and recovery procedures.

The specific processing by the specific processing unit 290 of the data processing device 12 in Application Example 1 is realized by the following means.

The present invention provides a server comprising a processor configured to acquire design information, specification information, and configuration information related to industrial equipment; preprocess the acquired information as document data; segment and structure the document data; store the structured document data in a storage device; generate distributed representations for the segmented document data; construct an index structure based on the distributed representations; select document data having a high relevance according to a predetermined search condition or event information; generate a prompt sentence to be input to a generative artificial intelligence model on the basis of the selected document data and instruction information including work content or accident content; transmit the prompt sentence to the generative artificial intelligence model so as to cause the generative artificial intelligence model to execute analysis processing; generate, on the basis of an analysis result output from the generative artificial intelligence model, work procedure information or recovery procedure information for the industrial equipment as structured instruction data; distribute the structured instruction data to a terminal device; collect work execution status information and feedback information from the terminal device; update contents of the work procedure information or the recovery procedure information on the basis of the work execution status information and the feedback information; reuse updated instruction data as additional learning data for the generative artificial intelligence model or as data for generating a subsequent prompt sentence; and, in response to occurrence of an accident, input the design information, the specification information, the configuration information, and past accident information to the generative artificial intelligence model, predict an impact range, and generate optimal recovery procedure information on the basis of a prediction result and past patterns. This enables the server to improve the technical performance of the computer system by reducing the amount of irrelevant data processed and transmitted to the generative artificial intelligence model, by accelerating retrieval and selection of contextually appropriate document segments via the index structure and distributed representations, by optimizing the content and structure of prompt sentences for more accurate and efficient model inference, and by dynamically adapting subsequent work and recovery procedures through systematic use of execution status and feedback information, thereby enhancing responsiveness, resource efficiency, and reliability of computer-implemented support for operation and recovery of industrial equipment.

The term “processor” refers to a hardware or virtual processing unit, such as a central processing unit or a processing core in a computing device, that executes instructions of a program to perform data processing operations described in the present disclosure. The term “industrial equipment” refers to machinery, apparatus, or systems used in industrial or commercial environments for production, processing, monitoring, or control, including but not limited to manufacturing lines, plant facilities, and associated control systems. The term “design information” refers to technical data that describes the structure, configuration, and functional relationships of industrial equipment, including diagrams, schematics, and descriptive documents specifying how components are arranged and interconnected.

The term “specification information” refers to technical data that defines functional requirements, performance parameters, operating conditions, and constraints of industrial equipment, including parameter tables, operating limits, and procedural specifications. The term “configuration information” refers to data that represents the composition, arrangement, and interconnection of components or subsystems of industrial equipment at a given point in time, including identifiers, topology information, and relationship data among components.

The term “document data” refers to digital data representing textual or mixed-media technical documents, such as design information, specification information, or configuration information, after being imported into and processed within a computing system.

The term “preprocess” refers to a series of operations applied to raw document data, including normalization, cleaning, segmentation, and metadata assignment, in order to convert the document data into a form suitable for indexing, retrieval, and use as input to a model.

The term “segment” refers to the operation of dividing document data into smaller units, such as paragraphs, sections, or logical chunks, each of which can be independently indexed, retrieved, or provided as part of a prompt sentence.

The term “structure” refers to the operation of organizing document data into a defined schema, where each segment is associated with metadata such as document type, version, equipment identifier, and section label, enabling efficient search and processing.

The term “distributed representation” refers to a numerical vector or embedding that encodes semantic information of a segment of document data in a continuous multi-dimensional space, such that similarity between segments can be computed using vector operations.

The term “index structure” refers to a data structure that organizes distributed representations and associated metadata to enable efficient similarity search, retrieval, and ranking of document segments in response to a query or event.

The term “search condition” refers to information specifying a retrieval requirement, such as a query text, an equipment identifier, a task type, or an incident type, which is used by the system to select relevant document data.

The term “event information” refers to data describing an event related to industrial equipment, such as an alarm, an incident, a maintenance request, or a design change, which triggers retrieval and analysis operations in the system.

The term “instruction information” refers to data that specifies a required task, operation, or analysis target, including information about work content, accident content, or desired output type, used in constructing a prompt sentence.

The term “prompt sentence” refers to a structured textual input, including instructions, context, and constraints, that is provided to a generative artificial intelligence model to cause the model to perform a specific analysis or generation task.

The term “generative artificial intelligence model” refers to a machine-learned model, such as a large language model, that has been trained on large amounts of data to generate or transform text or other data in response to input prompts.

The term “analysis processing” refers to computation performed by the generative artificial intelligence model on the basis of a prompt sentence, including interpretation of the provided context and generation of output such as procedures, predictions, or summaries.

The term “work procedure information” refers to information describing a sequence of steps, checks, and safety measures to be performed on industrial equipment during normal operation, setup, assembly, maintenance, or inspection.

The term “recovery procedure information” refers to information describing a sequence of steps, checks, and safety measures to be performed on industrial equipment to restore a normal state after an accident, fault, or abnormal condition.

The term “structured instruction data” refers to instruction data represented in a predefined schema, including elements such as step identifiers, textual descriptions, checklists, safety notes, and associated metadata, suitable for machine processing and terminal display. The term “terminal device” refers to a computing device used by an operator, such as a handheld device, tablet, workstation, or control panel, that can receive, display, and transmit instruction data and feedback information.

The term “work execution status information” refers to data indicating the progress and execution state of work procedures or recovery procedures, including step completion flags, timestamps, and intermediate observations recorded during execution.

The term “feedback information” refers to data entered by an operator or automatically collected from the field, indicating assessments, issues, comments, or anomalies related to the presented procedures or system behavior.

The term “additional learning data” refers to data used to further train or adapt a generative artificial intelligence model, including updated instruction data, feedback-augmented examples, or corrected outputs derived from field execution.

The term “subsequent prompt sentence” refers to a prompt sentence generated after previous executions or feedback have been obtained, the content of which is adjusted based on accumulated work execution status information and feedback information.

The term “accident” refers to an abnormal event or fault condition in industrial equipment, including failures, alarms, or hazardous situations that require analysis of an impact range and generation of recovery procedures.

The term “past accident information” refers to historical data about previous accidents, including incident logs, causes, affected equipment, and previously used recovery procedures, stored and used for pattern analysis.

The term “impact range” refers to a set of components, subsystems, processes, or areas that are predicted to be affected by an accident or abnormal condition, as determined on the basis of design information, configuration information, and model analysis.

The term “past patterns” refers to recurring relationships or trends derived from past accident information and operational data, indicating how certain faults propagate and how effective particular recovery actions have been.

The term “operator” refers to a human user who interacts with the terminal device, receives procedure information, executes physical or supervisory actions on industrial equipment, and provides feedback or status information to the system.

The term “progress information” refers to data indicating the current advancement through a set of steps in work procedure information or recovery procedure information, such as which steps are completed, in progress, or pending.

The term “completion information” refers to data indicating that a particular step or entire procedure has been finished, optionally including time of completion, responsible operator, and confirmation of required checks.

In one embodiment, a server implements the claimed system as a network-connected computing apparatus that cooperates with one or more terminal devices operated by a user in an industrial environment.

Server comprises at least one processor, a volatile memory, a non-volatile storage device, and a network interface. Server executes an operating system such as a general-purpose server operating system, and executes an application including a document processing module, an embedding generation module, an index management module, a prompt construction module, a model interaction module, and an instruction management module. Server further executes a web service module that communicates with terminal over a communication network using a protocol such as HTTPS.

Server uses a database management system such as a relational database and, in some embodiments, a vector index library or vector database for storing distributed representations. Server may employ a natural language processing library, a text extraction library for technical documents, and a software development kit for accessing an external generative AI model exposed as a network service. In other embodiments, server may execute a locally hosted generative AI model implemented as a transformer-based neural network. Server acquires design information, specification information, and configuration information of industrial equipment from storage. The industrial equipment may include processing machinery, assembly robots, transport equipment, measurement units, and control systems installed in an industrial plant. Server treats the design information, specification information, and configuration information as document data. Server converts digital files such as text files, technical reports, or diagram descriptions into normalized internal text representations by applying character encoding normalization, removal of control characters, and unification of line breaks. Server associates each document with metadata including document type, version, equipment identifier, and applicable process area.

Server segments each normalized document into multiple segments. Server may use sentence boundary detection and heading detection to identify logical sections such as “Assembly Procedure”, “Inspection Procedure”, “Safety Notes”, and “Control Logic Description”. Server assigns a segment identifier to each segment and stores the segment text and metadata into the database as structured records. In some embodiments, server additionally converts structured diagrams such as piping and instrumentation diagrams into textual relationships, for example, by extracting lists of component identifiers, connection types, and flow directions and storing them as separate configuration information records.

Server generates a distributed representation for each segment by applying an embedding function. In one embodiment, server calls an embedding model that maps input text to a fixed-dimensional real-valued vector. The embedding model may be a neural network trained on large technical corpora to reflect semantic similarity as vector proximity. Server stores each embedding vector in association with the corresponding segment identifier in a vector index. Server constructs an index structure that enables fast approximate nearest-neighbor search, such as an inverted file index, a hierarchical graph index, or a product quantization index. Server thereby enables the processor to identify relevant segments with reduced time complexity compared to linear text search.

Server uses the index structure to select document data having high relevance to a particular search condition or event information. When a new work instruction is required, server uses a search condition including at least an equipment identifier, a task type, and an operation mode, and optionally text keywords supplied by user. Server generates an embedding for the search condition text and executes a similarity search over the stored segment embeddings. By using precomputed embeddings and the index structure, server reduces search latency and memory accesses compared to conventional keyword-based full-text search, thereby improving computational efficiency.

Server constructs a prompt sentence to be input to a generative AI model by combining selected document segments and instruction information. The generative AI model is implemented as a transformer-based neural network that includes an input embedding layer, multiple self-attention layers, and an output projection layer. The model includes tens of layers, and each layer employs multi-head attention with learned weight matrices and a feed-forward network. The model has been trained using gradient-based optimization, where the loss function includes a cross-entropy term that measures the difference between predicted token distributions and ground-truth tokens. During training, model parameters such as attention weights and feed-forward weights are updated using backpropagation and stochastic gradient descent or a variant such as Adam.

Server, in one embodiment, uses a generative AI model that is pre-trained on general technical text and optionally fine-tuned on industrial equipment documentation. For fine-tuning, server constructs training pairs of input sequences (including design information, specification information, and configuration information) and desired output sequences (including validated work procedures and recovery procedures). Server uploads such training pairs to a training pipeline. The training pipeline calculates a loss function, propagates gradients through all layers of the transformer architecture, and updates weight parameters. By incorporating domain-specific documentation and validated procedures, server causes the generative AI model to reduce prediction error for tokens related to industrial components and procedures.

Server generates the prompt sentence using a non-conventional structure that explicitly separates instructions and technical context. Server composes a section that defines the role of the generative AI model, a section that describes required output format and constraints, and sections that embed the most relevant document segments retrieved from the index. For example, server may generate the following prompt sentence:

### System Message:

“You are an expert engineer responsible for generating safe and efficient work procedures for industrial equipment. You must follow the instructions strictly and use only the provided documentation as technical authority.”

### User Message:

“Based on the following design and specification information, create optimized work instructions.

Output numbered steps and a checklist. Each step must be concise and must reference relevant components by their identifiers.

### Design Information:

[Segment 1 text]
[Segment 2 text]

### Specification Information:

[Segment 3 text]”

By using this multi-part prompt sentence, server constrains the generative AI model to generate output in a structured way. This structure allows server to parse the output effectively and reduces the risk of irrelevant information, thereby decreasing the need for post-processing and improving the predictability of model responses. The explicit constraints in the prompt sentence are not conventional in human-authored procedures and reflect specific formatting requirements to optimize computer parsing.

Server transmits the prompt sentence to the generative AI model using a transport protocol such as HTTPS. When the generative AI model executes in a remote computing environment, server uses a model interaction module to serialize the prompt sentence into an application-level request, send it through the network interface, and wait for the response. The remote model applies its internal transformer architecture to compute output token probabilities at each generation step based on attention over the prompt tokens and previously generated tokens. The model uses a decoding algorithm such as greedy decoding or sampling with a temperature parameter to select tokens. The model then returns the generated sequence as a textual output.

Server receives the generated output and parses it according to the required structure. If the prompt sentence requested numbered steps, server identifies lines starting with numeric patterns and stores each as a separate step record. If the prompt sentence requested checklists or safety cautions, server detects labeled sections such as “Checklist:” or “Safety Notes:” and stores corresponding items in structured format. Server creates structured instruction data that includes fields for step identifiers, textual content, required tools, safety notes, and related component identifiers. Server stores the structured instruction data in the database for subsequent retrieval.

Server distributes the structured instruction data to terminal. Terminal is implemented as a handheld device, a tablet computer, or an operator station with a processor, a display, input means such as a touch panel, and a communication interface. Terminal executes a client application that requests the latest instructions for a specified equipment identifier and task. Terminal receives the structured instruction data and renders each step sequentially, with controls for the operator to mark steps as complete or to request additional details. User uses terminal to perform operations on the industrial equipment according to the displayed instructions. User may, for example, attach a specified component to another component, adjust a control parameter on an industrial controller, or perform an inspection. As user completes each step, user inputs a confirmation via terminal. If user encounters an issue such as unclear wording or impractical ordering, user may input feedback text and select a predefined problem category such as “ambiguous description” or “missing safety precaution”.

Terminal transmits work execution status information and feedback information to server. Server receives this data and updates the stored instruction records by attaching execution timestamps, completion flags, and feedback annotations. Server also aggregates statistics such as average completion time per step, error frequency per step, and feedback frequency per step. Server uses these statistics as evaluation indices to identify steps that consistently cause delays or confusion.

Server uses the evaluation indices and feedback information to generate optimized instruction revisions. Server constructs a new prompt sentence that includes both the original instructions and summarized feedback. For example, server may generate a prompt sentence such as:

### System Message:

“You are revising work procedures for industrial equipment. Improve clarity, safety, and efficiency according to operator feedback. Preserve correct technical content.”

### User Message:

“Here are the current instructions and feedback from operators.

Rewrite the instructions to resolve the issues.

### Current Instructions:

1. Attach part A to part B.
2. Add part C.

### Feedback:

The location of alignment marks is unclear.
The required torque value is missing.
The order of tool preparation is inefficient.

Output revised instructions as numbered steps and include a safety checklist.”

Server transmits this prompt sentence to the generative AI model. The generative AI model generates an updated instruction sequence that addresses the identified issues. Server parses the revised sequence and stores a new version of the structured instruction data. Server thereby creates an iterative feedback loop where model outputs and real-world execution data inform each other. This feedback loop is not equivalent to mere automation of human instruction writing. The loop leverages the model's ability to generalize from feedback patterns across many tasks and to adjust language and structure in a way that human authors may not systematically achieve.

Server, in accident scenarios, uses the same infrastructure to predict impact range and generate recovery procedures. When an abnormal event occurs, an event source such as an industrial controller or monitoring system transmits event information to server. The event information may include an alarm identifier, time of occurrence, measured values, and the identifier of affected equipment. Server retrieves design information and configuration information that describe the physical and control relationships of the affected equipment. Server also retrieves past accident information that shares similar characteristics. Server runs a similarity search over embeddings of past accident descriptions and configuration snapshots to locate accidents that are most similar in terms of root cause, affected components, and propagation path.

Server constructs a prompt sentence that includes the current event information, relevant design and configuration segments, and summaries of similar past accidents and responses. For example, server may generate a prompt sentence as follows:

### System Message:

“You are a safety and reliability engineer. You must analyze the impact range of an abnormal event and propose concrete recovery procedures based on the provided documentation and incident history. You must explicitly identify affected components and required isolation steps.”

### User Message:

“An overheat alarm has been triggered at heater H-102.

Based on the following design, specification, configuration, and past accident information, predict the impact range and propose recovery procedures.

### Design Information:

[Relevant design segments]

### Configuration Information:

[Relevant configuration segments]

### Past Accident Information:

[Summaries of similar overheating incidents]”

Server sends the prompt sentence to the generative AI model. The generative AI model, by attending to component relationships and past patterns represented in its hidden states, generates a description of the impact range and detailed recovery procedures, including shutdown sequences, isolation valve operations, and inspection points. Server parses the generated output into structured recovery procedure information and identifies a list of affected components. Server then distributes the recovery procedure information to terminal devices placed near the affected equipment, enabling user to follow a rigorous, model-generated plan under time pressure.

Server's use of distributed representations and index structures yields technical effects beyond mere convenience. By segmenting documents and precomputing embeddings, server reduces the amount of text transmitted to the generative AI model for each request. Instead of sending entire manuals, server selects only segments with high semantic relevance, thereby shortening prompt sentences and reducing model input length. This reduction improves model inference speed and reduces computational cost because the transformer architecture has time complexity that grows at least quadratically with input sequence length. By reducing sequence length, server lowers latency and energy consumption of model inference. Server further improves technical performance by structuring outputs in machine-readable form. By requiring the generative AI model to emit numbered steps and labeled sections, server simplifies downstream parsing and storage, which reduces CPU cycles and memory allocations required for post-processing. The structured format also enables rapid filtering and comparison of procedure versions, facilitating incremental updates and minimizing duplication in storage.

Server uses non-conventional rule sets for constructing prompt sentences and for selecting documents. For example, server may enforce rules that each prompt sentence includes at most a specified number of tokens and that segments from conflicting design versions are never paired in the same prompt. Server may perform a pre-filtering operation in which configuration information is used to discard segments that refer to subsystems physically disconnected from the current equipment. These non-traditional rules are tailored to the limitations of transformer-based generative models and are not intuitive in purely human workflows. The rules yield a direct technical effect by preventing irrelevant or contradictory information from being sent to the model, thus lowering the probability of erroneous model outputs.

Server, in some embodiments, hosts the generative AI model locally. In such cases, server stores the model parameters in memory and executes forward passes of the transformer network on an accelerator such as a graphics processing unit. Server partitions model parameters across devices if needed and uses optimized linear algebra libraries to accelerate matrix multiplications in attention and feed-forward layers. Server then avoids network latency and can further optimize performance by batching multiple prompt sentences into a single inference call, sharing computations across similar prompts.

Server may apply additional machine learning techniques to enhance robustness. Server may implement a confidence estimator that computes a score for model outputs based on internal token probabilities, output length, and presence of required sections. When the confidence is below a threshold, server may either request regeneration from the model with modified parameters or highlight the output to user as provisional. Server can also apply rule-based post-checks to ensure that recommended recovery steps never violate known safety constraints stored in configuration information.

In alternative embodiments, server may use different neural architectures for generating distributed representations and for instruction generation. For example, server may employ a dual-encoder model for embeddings, trained to place related design segments and tasks near each other in vector space. Server may also use specialized fine-tuning for safety-critical language, where a secondary classifier scans generated instructions for prohibited patterns. Terminal cooperates with server by executing a user interface tailored to the structured instruction data. Terminal maps each step in work procedure information or recovery procedure information to a visual element and stores a local copy of the steps for offline use. When connectivity is limited, terminal can still guide user through previously downloaded instructions, and synchronize execution status with server once connectivity is restored. This design reduces communication load and improves reliability in harsh industrial environments. User interacts with terminal and with the industrial equipment according to the instructions. User's actions and feedback, when captured and transmitted to server, form part of an iterative improvement cycle that affects the behavior of the generative AI model through updated additional learning data or adjusted prompt sentences. Over time, the system becomes more efficient in computing and storage usage and more accurate in instruction generation.

By implementing the described data structures, neural network architecture, prompt construction rules, and feedback loop, server improves computer technology itself. Server reduces computational complexity and memory usage in document retrieval and prompt construction, reduces latency and resource consumption in model inference, and enhances the accuracy and stability of generated instructions. These effects are realized at the level of data representation and algorithmic processing in the computer system and are not limited to mere automation of human judgment or business logic.

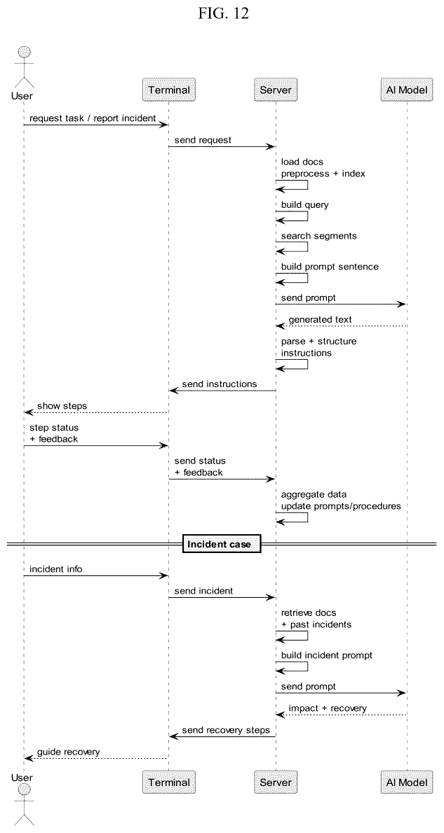

The following describes the processing flow using FIG. 12.

### Step 1

Server acquires raw technical documents.

Server receives, as input, document identifiers or equipment identifiers from a configuration database or an external management system. Based on this input, server reads digital files containing design information, specification information, and configuration information related to industrial equipment from a storage device such as a file system or a document repository. Server opens formats such as text files and technical reports and loads their contents into memory as raw text strings. Server outputs normalized raw text data associated with metadata such as document ID, version, and equipment ID.

### Step 2

Server preprocesses and segments document data.

Server takes, as input, the normalized raw text data and associated metadata from Step 1. Server performs data processing including character encoding normalization, whitespace normalization, removal of control characters, and unification of line breaks. Server then applies segmentation logic that detects headings, paragraph boundaries, and structural markers to divide each document into segments, such as procedure sections, specification sections, and configuration descriptions. For each segment, server assigns a segment ID and attaches metadata including document type, section title, and applicable equipment. Server outputs a collection of structured segment records, each containing segment text and metadata.

### Step 3

Server generates distributed representations and builds an index.

Server receives, as input, the structured segment records produced in Step 2. For each segment, server calls an embedding function implemented by an embedding model to convert the segment text into a fixed-dimensional numerical vector. This involves tokenizing the text, mapping tokens to internal embeddings, and applying a neural network that outputs a real-valued vector. Server then stores each vector, along with the corresponding segment ID and metadata, into a vector index structure. Server may build or update index data structures, such as inverted lists or graph-based indices, to enable efficient similarity search. Server outputs an updated index that maps semantic embeddings to segment IDs and a persisted store of segment embeddings and metadata.

### Step 4

Server receives a work or incident request.

Server takes, as input, a request from an external system or terminal, which may include an equipment ID, a task type (for example, assembly, maintenance, inspection), and optionally an incident type or alarm code. Server parses the request and normalizes the parameters into a standard internal request representation. If the request corresponds to an incident, server also retrieves event data, such as timestamps, sensor values, and alarm identifiers, from a monitoring system. Server outputs a structured request object containing the requested operation type, the relevant equipment identifier, and any incident-related attributes.

### Step 5

Server retrieves relevant segments using the index.

Server receives, as input, the structured request object from Step 4 and the index created in Step 3. Server constructs a search query text that may include the task type, equipment identifier, and any key phrases derived from the request. Server converts this search query text into an embedding vector using the same embedding model as in Step 3. Server then executes a similarity search over the stored segment embeddings using the index, calculating similarity scores, for example cosine similarity, between the query vector and each candidate vector. Server selects a subset of segments with highest similarity scores and filters them by metadata, such as matching equipment ID or document version. Server outputs a ranked list of relevant segment records, each containing segment text and associated metadata.

### Step 6

Server constructs a prompt sentence for the generative AI model.

Server takes, as input, the ranked list of relevant segment records from Step 5 and the structured request object from Step 4. Server generates a prompt sentence by assembling multiple text sections. Server first creates a role description section (system message) that instructs the generative AI model on its role, such as generating work procedures or analyzing impact ranges. Server then creates a task description section (user message) that specifies the required output format, including requirements for numbered steps, checklists, and safety notes. Server concatenates the most relevant segment texts under labeled sections, such as “Design information” and “Specification information,” while ensuring the combined length does not exceed a predefined token limit. Through this processing, server converts structured data into a single textual prompt sequence that encodes both instructions and technical context. Server outputs a fully formed prompt sentence ready to be sent to the generative AI model.

### Step 7

Server sends the prompt sentence to the generative AI model and receives analysis results. Server receives, as input, the constructed prompt sentence from Step 6. Server serializes the prompt sentence into a request format required by the generative AI model service and transmits it over a network using a communication protocol such as HTTPS. Within the generative AI model, the prompt sentence is tokenized, converted to token embeddings, and processed by a transformer architecture that applies multi-head attention and feed-forward operations layer by layer to compute output token distributions. The model then generates an output sequence representing, for example, work procedures, impact analysis, or recovery procedures. Server receives the generated text from the model as a response. Server outputs the raw generated text as analysis result data associated with the original request.

### Step 8

Server parses and structures the generated instructions.

Server takes, as input, the raw generated text from Step 7. Server applies pattern recognition and rule-based parsing to detect numbered steps, checklist items, safety notes, and section headers in the generated text. Server splits the text into individual instruction units based on detected numbering and labels. For each unit, server creates a structured record including a step identifier, description text, inferred step type (for example, action, check, or safety), and any referenced component identifiers. By converting the free-form model output into structured records, server enables efficient storage and later retrieval. Server outputs structured instruction data containing an ordered list of steps, optional checklist items, and associated metadata for the requested task or incident.

### Step 9

Server stores and versions the structured instruction data.

Server receives, as input, the structured instruction data from Step 8 and the original request object from Step 4. Server assigns a procedure identifier and version number to the instruction data, linking it to the relevant equipment and operation type. Server writes the instruction data into a database, indexing it by equipment ID, task type, and version. Server also records creation time, the prompt sentence used, and a reference to the generative AI model configuration. This storage operation turns transient model output into persistent procedural information. Server outputs a reference to the stored procedure, such as a procedure ID or URL, which can be used by terminal to retrieve the instructions.

### Step 10

Server delivers instructions to terminal.

Server takes, as input, a request from terminal containing a procedure identifier or equipment identifier. Server queries the database for the corresponding structured instruction data stored in Step 9. Server packages the instruction data into a response format that includes the ordered steps, checklist items, and safety notes. Server may filter or adapt the data to match the capabilities of the requesting terminal, such as limiting the amount of information per page or including language localization. Server outputs a formatted instruction payload and sends it to terminal over a network connection.

### Step 11

Terminal displays instructions to user and collects execution actions.

Terminal receives, as input, the instruction payload from server in Step 10. Terminal parses the payload and creates user interface elements corresponding to each step and checklist item. Terminal displays step descriptions in sequence on the screen, with interactive components such as buttons or checkboxes. As user performs actions in the physical environment according to the displayed instructions, user operates terminal to mark steps as started, in progress, or completed, and to open any additional detail views as needed. Terminal collects these user interactions and converts them into work execution status information that includes step identifiers, status flags, timestamps, and optional user comments. Terminal outputs this execution status information as structured data ready to be sent back to server.

### Step 12

User executes work procedures and provides feedback.

User receives, as input, the visual display of instructions and statuses from terminal in Step 11. Based on these instructions, user physically manipulates industrial equipment, such as assembling parts, adjusting valves, or performing inspections. During or after each step, user may input feedback through terminal, including free-text comments describing difficulties, perceived ambiguities, or suggestions, and may also select predefined categories for issues. The combination of physical actions and digital feedback constitutes the human contribution to the system's operational loop. User outputs implicit execution results through physical completion and explicit feedback data through terminal interactions.

### Step 13

Terminal transmits execution status and feedback to server.

Terminal takes, as input, the work execution status information and feedback information captured in Step 11 and Step 12. Terminal aggregates this data into a report payload, including procedure identifiers, step-level status, timestamps, and feedback content. Terminal may temporarily buffer this data if connectivity is intermittent. When a connection is available, terminal sends the report payload to server using a secure network protocol. Terminal outputs a transmitted status log indicating successful or failed delivery attempts for each report.

### Step 14

Server aggregates execution data and evaluates procedure performance.

Server receives, as input, the report payloads from terminal in Step 13. Server writes individual execution events into a database table that records which user executed which step at what time and with what feedback. Server then runs aggregation queries or scheduled analytic routines to compute evaluation indices such as average completion time per step, error or issue frequency per step, and relative frequency of different feedback categories. Server may further compute derived metrics, such as variance of completion times and correlation between step characteristics and issue rates. Based on these calculations, server identifies steps that systematically cause delays or confusion. Server outputs a summarized evaluation report that links problematic steps to quantitative indices and collected feedback excerpts.

### Step 15

Server refines prompts and procedures based on evaluation indices.

Server takes, as input, the evaluation report produced in Step 14 and the existing instruction data for the corresponding procedures. Server constructs an updated prompt sentence for the generative AI model that includes the current instructions and summarized feedback or performance metrics. Server may, for example, append notes such as “Step 3 frequently causes confusion; operators report missing torque values” to the prompt sentence. Server then sends this updated prompt sentence to the generative AI model to generate revised instructions, similar to Step 7. After receiving the revised instructions, server repeats parsing and structuring operations as in Step 8 and updates the stored procedure version as in Step 9. Server thus outputs new instruction versions and modified prompt templates that reflect learned improvements.

### Step 16

Server performs incident-specific impact analysis and recovery planning.

Server receives, as input, incident-related event information from monitoring systems and, optionally, user reports from terminal. Server retrieves relevant design information, configuration information, and past accident information from the document store and embedding index, using similarity search as in Step 5. Server constructs a prompt sentence that embeds the current incident description, the related design and configuration segments, and short summaries of similar past incidents. Server sends this prompt sentence to the generative AI model and receives generated output describing an impact range and recommended recovery procedures. Server parses this output into structured recovery procedure information and a list of affected components. Server outputs this structured incident response plan and distributes it to terminals associated with the affected equipment.

### Step 17

Terminal guides user through recovery procedures and logs actions.

Terminal takes, as input, the structured recovery procedure information from server in Step 16. Terminal presents emergency steps with visual emphasis, such as color coding or warning icons, and may require explicit confirmations for safety-critical actions. As user executes the recovery actions on industrial equipment, user uses terminal to confirm step completion and record observations such as measured values or visible anomalies. Terminal collects this data as incident-specific execution status and later transmits it to server in the same manner as in Step 13. Terminal outputs a digital log of recovery operations synchronized with the incident identifiers.

### Step 18

Server incorporates incident logs into learning and optimization.

Server receives, as input, the incident-specific execution status and recovery logs from terminal in Step 17. Server stores these logs along with the associated incident description, impact predictions, and recovery procedures that were generated. Server uses these logs to refine similarity search criteria for future incidents and to construct new training examples or prompt patterns for the generative AI model. Server may, for example, adjust how much weight is given to particular configuration relationships when selecting context segments. By relating predicted impact ranges and actual observed effects, server tunes its retrieval and prompt construction rules to minimize future prediction errors. Server outputs updated retrieval configurations, revised prompt sentence templates, and, when applicable, new fine-tuning datasets that gradually improve the overall system performance.

It is also possible to incorporate an emotion engine for estimating the user's emotions. That is, the specific processing unit 290 may estimate the user's emotions using an emotion identification model 59, and perform specific processing based on the estimated emotions.

### Example 2

Description follows regarding a flow of the specific processing in an Example 2. The units of the system described below are implemented by the data processing device 12 and the smart device 14. The data processing device 12 is called a “server” and the smart device 14 is called a “terminal”.

In complex information processing environments that manage design, specification, and configuration information of industrial facilities, incident response often depends on manual retrieval and interpretation of large volumes of technical documents. Conventional systems typically store such information in document repositories or configuration management databases and may provide keyword-based search functions. However, these systems generally require human operators to understand the incident context, formulate appropriate queries, correlate heterogeneous documents, and synthesize the relevant design information needed for root cause analysis and recovery planning.

In particular, when an accident or service failure occurs, multiple departments must rapidly understand which functional elements, connections, and configuration items are implicated. Existing tools lack the capability to automatically convert raw, unstructured accident information—such as timestamps, locations, impact scopes, and error messages—into structured, incident-specific design views. As a result, incident handling is delayed by the time required for experts to manually map symptoms to system design, and to identify appropriate recovery procedures.

While generative AI models and large-scale language models have recently been applied to general question answering, such models are usually accessed in an ad hoc manner through generic chat interfaces. Conventional approaches do not tightly integrate such models with normalized incident data, internal design repositories, and structured output formats tailored to multi-department technical investigation. Consequently, prior systems do not fully exploit generative AI capabilities to improve core computer system functions such as context construction, information retrieval orchestration, and structured response generation for incident management.

Moreover, most existing systems treat user input as purely factual data and do not consider the emotional state of human operators. Under high pressure during critical incidents, operators may become stressed or overwhelmed, and conventional interfaces that present excessively detailed or poorly structured technical information can further degrade decision-making. Traditional systems do not adapt the granularity or presentation style of technical content based on inferred user state, and therefore cannot optimize human-computer interaction during incident response.

Accordingly, there is a need for a computer-implemented system that technically improves incident response by: (i) transforming unstructured accident information into normalized, structured data; (ii) automatically constructing and issuing enriched prompt sentences to a generative AI model; (iii) integrating the generated text with internal design and configuration repositories to produce structured, machine-usable design information specific to the incident; and (iv) dynamically adjusting the level of detail and expression format of the presented information based on analysis of the user's emotional state. Such a system should enhance the functioning of the computer itself in orchestrating data processing, model interaction, and interface behavior, thereby reducing manual effort, lowering time to diagnosis, and improving the reliability and usability of incident management operations.

The specific processing by the specific processing unit 290 of the data processing device 12 in Example 2 is realized by the following means.

The present invention provides a server comprising a processor configured to learn design information, specification information, and configuration information of industrial facilities by performing additional training on a large-scale language model having a scale comparable to a generative AI model; to receive accident information transmitted from a user terminal by using a secure communication method and to normalize the accident information as structured data including time information, location information, impact range information, and failure content information; to generate a prompt sentence for input to the large-scale language model based on the normalized accident information and to generate an internal prompt sentence by adding context information including system configuration information and version information to the prompt sentence; to transmit the internal prompt sentence together with parameter information to the generative AI model and to acquire an analysis result text from the generative AI model, the analysis result text including design information, specification summary information, and component information related to the accident information; to analyze the analysis result text to extract related functional elements, connection relationships, and setting items and to generate structured design information including area information, document reference information, and countermeasure candidate information based on the extracted result; to acquire reference information of related design documents and drawings from a document management device or an information retrieval device based on the structured design information and to generate accident-response design information by adding the reference information to the structured design information; to format the accident-response design information into a predetermined display format, to transmit the accident-response design information to the user terminal, and to support identification of an accident cause and planning of a countermeasure policy by users of a plurality of departments; to analyze past accident data by using the generative AI model, to estimate an impact range in a current accident, and to present recovery procedure candidates based on patterns learned from the past accident data; and to analyze an emotional state of a user based on input content or operation history acquired from the user and to adjust a level of detail or an expression format of the design information to be presented according to the emotional state. This enables a technical improvement of the computer system in incident response by allowing the server to automatically transform raw accident inputs into enriched, model-ready prompt sentences, orchestrate interaction with a generative AI model, synthesize structured, incident-specific design information linked to internal repositories, and dynamically adapt the presentation of such information to the operator's cognitive state, thereby reducing processing latency, lowering operator workload, and enhancing reliability and usability of computer-implemented incident management.

The term “industrial facilities” refers to large-scale physical or virtual installations that provide commercial or public services, including but not limited to plants, data centers, transportation systems, communication systems, and associated control systems.

The term “design information” refers to information describing structural, functional, or architectural aspects of a system, including component layouts, interfaces, relationships between subsystems, and overall system topology.

The term “specification information” refers to information defining required behaviors, performance characteristics, constraints, and functional requirements of a system or component, including protocols, thresholds, and operational conditions.

The term “configuration information” refers to information indicating concrete parameter values, settings, and deployment states of hardware or software resources in a system, including versions, option flags, and environment-specific settings.

The term “large-scale language model” refers to a machine-learned statistical model having a large number of parameters and trained on extensive text data to perform natural language processing and generation tasks.

The term “generative AI model” refers to a machine-learned model configured to generate new content, including natural language text, based on input data, and including but not limited to large-scale language models.

The term “additional training” refers to a process of further training a pre-trained model using task-specific or domain-specific data so as to adapt the model to a particular application area. The term “user terminal” refers to an information processing apparatus operated by a user, including but not limited to a workstation, a personal computer, a tablet device, a smartphone, or any network-connected client device.

The term “secure communication method” refers to a communication protocol or mechanism that provides at least data integrity and confidentiality, including but not limited to protocols implementing encryption and authentication.

The term “accident information” refers to information representing an occurrence of an abnormal event or failure in a system, including data such as time of occurrence, location, impact range, and error messages.

The term “structured data” refers to data organized according to a predefined schema or format, such as fields, keys, or tags, enabling deterministic parsing and processing by a computer.

The term “time information” refers to data indicating when an accident occurred, including but not limited to timestamps, time intervals, or time zones.

The term “location information” refers to data indicating where an accident occurred, including but not limited to physical sites, logical system segments, network zones, or equipment identifiers.

The term “impact range information” refers to data indicating a scope of influence of an accident, including affected services, components, users, or geographical areas.

The term “failure content information” refers to data describing symptoms or manifestations of a failure, including error codes, error messages, performance degradation indicators, or functional anomalies.

The term “prompt sentence” refers to a natural language expression generated or used by a system to instruct or query a generative AI model regarding a particular task or question. The term “internal prompt sentence” refers to a prompt sentence that has been augmented by the system with additional context information, including but not limited to configuration, version, or structural metadata, prior to being supplied to a generative AI model.

The term “context information” refers to auxiliary data that supplements primary input data, such as system configuration information, version information, or environment descriptors, used to provide a richer basis for processing.

The term “system configuration information” refers to information that describes a composition and interconnection of system components, including nodes, services, interfaces, and deployment topology.

The term “version information” refers to data indicating version identifiers or release levels of hardware, software, or configuration artifacts included in a system.

The term “parameter information” refers to data defining control values or options for executing a model or algorithm, including settings such as temperature, maximum output length, or output format.

The term “analysis result text” refers to natural language text output by a generative AI model in response to an input prompt, the text including explanations, inferences, or derived information.

The term “specification summary information” refers to condensed descriptions of key specification points extracted or generated from more detailed specification information. The term “component information” refers to information describing individual functional units of a system, including component identifiers, roles, interfaces, and relationships.

The term “functional elements” refers to logical units of functionality within a system, such as services, modules, subsystems, or processes that perform defined operations.

The term “connection relationships” refers to logical or physical links between functional elements, including data flows, control flows, interfaces, and communication paths.

The term “setting items” refers to individual configuration parameters or options that can be assigned values to control behavior of system components.

The term “structured design information” refers to design-related information arranged in a machine-readable, organized form including explicit fields such as element identifiers, relationships, and references.

The term “area information” refers to data indicating particular sections, domains, or portions of a system or facility to which certain design information or incident information pertains. The term “document reference information” refers to identifiers or links that enable access to external documents, including document identifiers, storage locations, and access paths. The term “countermeasure candidate information” refers to proposed or potential actions, procedures, or changes intended to mitigate or resolve an accident or failure.

The term “document management device” refers to an information processing system or service that stores, indexes, and provides access to documents, including design documents and drawings.

The term “information retrieval device” refers to an information processing system or service that searches and returns data or documents based on queries, keywords, or identifiers.

The term “accident-response design information” refers to design-related information tailored to a particular accident, including relevant components, documents, and countermeasure candidates assembled for incident handling.

The term “display format” refers to a representation structure specifying how information is arranged for presentation on a user interface, including ordering, grouping, and visual emphasis of elements.

The term “past accident data” refers to stored records of previously occurred accidents, including associated structured and unstructured information, used for analysis and learning. The term “patterns learned from the past accident data” refers to correlations, trends, or models derived from analysis of past accident data, which can be used to infer likely impacts or effective recovery actions for new accidents.

The term “recovery procedure candidates” refers to one or more possible sequences of actions or steps proposed to restore system functionality after an accident.

The term “emotional state of a user” refers to an estimation of a psychological or affective condition of a user, such as stress level, confusion, or confidence, inferred from user behavior or input.

The term “input content” refers to text or other data explicitly provided by a user through an interface, such as descriptions, queries, or commands.

The term “operation history” refers to a record of user interactions with a system, including interface actions, navigation sequences, and response times.

The term “level of detail” refers to a degree of granularity or comprehensiveness in information presented to a user, such as summary-level information versus detailed technical descriptions.

The term “expression format” refers to a style or structure in which information is presented, such as bullet lists, step-by-step procedures, summarized text, or technical prose.

The term “information processing device” refers to hardware and software resources configured to perform computation, data storage, and communication functions, including servers and virtualized computing environments.

The term “external information providing device” refers to a system or service external to the server that supplies additional information such as documents, diagrams, or configuration data upon request.

In one embodiment, a server, a terminal, and a user cooperate to implement the invention.

The server is realized by one or more information processing devices such as rack-mounted computers or virtual machines operating in a data center. The server includes at least one multi-core central processing unit (CPU), a volatile memory, a non-volatile storage device, and a network interface. The server executes an operating system such as a general-purpose server operating system and runs application software implemented, for example, using a server-side framework. The server further includes an accelerator, such as a graphics processing unit (GPU) or tensor processing unit (TPU), when large-scale language model inference or training is executed locally.

The terminal is realized by a general-purpose client device such as a personal computer, a tablet device, or a smartphone. The terminal executes a client operating system such as a personal-computer operating system or a mobile operating system, and runs a web browser or a native application. The terminal includes a display device, an input device, a memory, and a communication interface. The terminal communicates with the server via a wired or wireless network using a secure transport protocol.

The user operates the terminal to input accident information and to view design information and countermeasure candidates. The user may be, for example, an operator in a control room, a maintenance engineer, or a system administrator.

The server stores, in the storage device, a set of design information, specification information, and configuration information for industrial facilities. The design information includes, for example, architectural diagrams, interface definitions, module dependency graphs, and topology descriptions. The specification information includes, for example, functional requirement descriptions, performance requirement tables, error condition definitions, and protocol specifications. The configuration information includes, for example, parameter sets for software components, threshold values, version identifiers, deployment mappings, and hardware configuration values. The server stores such information in a structured form using data structures such as relational tables, key-value stores, or document-oriented records, and additionally stores links to external document repositories and drawing repositories.

The server implements, in the memory, a large-scale language model serving module. The server uses a large-scale language model that is trained as a transformer-based neural network having multiple encoder-decoder or decoder-only layers, self-attention mechanisms, and tens of billions of trainable parameters. The server configures the model with token embeddings, positional encodings, multiple attention heads, feed-forward sublayers, and layer normalization units. The server trains the model in an initial stage using a generic corpus of natural language text. The server then performs additional training (fine-tuning) of the model using domain-specific text derived from the design information, specification information, configuration information, and past accident reports of industrial facilities.

The server executes the additional training by loading domain-specific training examples into memory, where each training example includes an input sequence and a target output sequence. The server defines a loss function such as a cross-entropy loss over token predictions. The server updates the weights of the transformer network by backpropagation using an optimization algorithm such as stochastic gradient descent or Adam. The server adjusts learning-rate parameters, batch sizes, and regularization parameters such as dropout rates to prevent overfitting to the industrial facility data. The server may augment the training data by applying data augmentation techniques such as paraphrasing, template-based generation of incident descriptions, or synonym substitution, thereby increasing model robustness and coverage.

The server stores, in association with the model parameters, metadata including model version identifiers, training dataset identifiers, and hyperparameter settings. The server uses this metadata when generating internal prompt sentences and analyzing model outputs, enabling traceability and reproducibility of design information generation.

The server further stores accident history data including time information, location information, impact range information, failure content information such as error codes and error messages, and manually recorded root causes and recovery procedures. The server normalizes these records into a schema that explicitly associates each accident with impacted components, configuration items, and documents. The server uses these records both as training data and as reference data for impact estimation and recovery procedure recommendation.

The terminal presents, on the display device, a user interface implemented using a graphical framework. The terminal obtains, from the server, a definition of input fields such as “date and time of incident,” “location,” “impacted service or subsystem,” “symptoms,” and “error messages.” The terminal renders fields for free-text input and for selection from pre-defined lists. The terminal can further present a field where the user may directly enter a prompt sentence intended for the generative AI model.

The user enters accident details, including, for example, a prompt sentence such as: “Please provide design information related to the incident where the system returns ‘Error 503: Service Unavailable’ for the payment API.”

Alternatively, the user may enter a prompt sentence such as:

“An incident occurred in the order processing service at 10:32 on January 15. The client applications receive ‘Error 503: Service Unavailable’. Please identify the related components and design documents.”

The terminal transmits such prompt sentences, together with structured accident metadata, to the server.

The server stores accident information received from the terminal as records in the storage device. The server applies validation rules to the received data, converts date and time strings to a canonical time format, maps free-text location and subsystem names to internal identifiers using lookup tables, and classifies impact range into categories such as “external API,” “batch processing,” “database access,” or “field device control.” The server extracts error codes and error message texts using pattern-matching algorithms or regular expressions and stores them as separate fields to facilitate subsequent analysis.

The server generates an internal prompt sentence that combines normalized accident fields with system context. The server uses a prompt-construction module that assembles natural language templates, inserts normalized field values, and appends additional context, such as model version identifiers, configuration snapshot identifiers, and relevant subsystem names. The server uses decision rules that select different template variations depending on the type of subsystem (for example, network, application, database, or field controller) and the detected error category. The server constructs internal prompt sentences in a consistent machine-generated style that is optimized to elicit structured, technically detailed responses from the generative AI model. The server thereby uses domain-adapted prompt engineering in a systematic, algorithmic manner rather than relying on ad hoc human phrasing. The server supplies the internal prompt sentence as tokenized input to the large-scale language model. When the model is deployed locally, the server converts the internal prompt sentence into a sequence of token identifiers using a tokenizer that maps substrings to integer codes. The server then feeds the token sequence through the transformer network by performing multi-head self-attention, matrix multiplications, and non-linear activations. The server retrieves, from the output layer, probability distributions over tokens and generates an output sequence by iterative decoding using strategies such as greedy decoding, beam search, or top-k sampling, subject to a maximum length constraint and temperature parameter. When the model is provided by an external generative AI service, the server transmits the internal prompt sentence and decoding parameters to the external service via a secure network interface and receives the generated text in response.

The server obtains, as analysis result text, a generated natural language description that may contain identification of related components, mention of probable failure mechanisms, references to configuration parameters such as timeout values or threshold values, and textual descriptions of recommended recovery steps. The server processes the analysis result text using a post-processing module that performs natural language parsing, entity recognition, and relation extraction. The server uses dictionaries of known component labels, configuration key names, and document identifiers to map terms in the generated text to internal identifiers. The server thereby converts the unstructured model output into structured design information.

The server organizes the structured design information into data structures such as hierarchical objects that include sections like “Summary,” “Affected Components,” “Configuration Items,” “Known Failure Patterns,” and “Recommended Recovery Procedures.” The server associates each component with its role in the facility, physical or logical location, and connection relationships with other components. The server links configuration items to parameter records stored in the configuration database and identifies current values versus recommended or default values based on model suggestions. The server enriches the structured design information by querying a document management device or an information retrieval device that stores design documents, drawings, and change history records. The server formulates search queries using component identifiers, configuration keys, and accident identifiers. The server retrieves metadata such as document titles, section headings, and figure references and attaches corresponding document reference information, including access paths or uniform resource identifiers, to the structured design information. The server may also generate short summaries of retrieved documents using additional passes through the generative AI model, under a constrained summarization prompt, to avoid transferring full document contents unnecessarily. This reduces communication load and improves response time.

The server formats the accident-response design information into a display-oriented representation. The server assigns each section of the structured design information to logical display regions such as a summary header, component list view, diagram reference panel, and countermeasure list. The server compresses or elides low-relevance data when the amount of information exceeds a threshold, thereby preventing overload of the terminal and reducing network transfer size. The server transmits the formatted information to the terminal using a compact structured representation.

The terminal receives the accident-response design information and renders it using a multi-pane layout. The terminal displays a summary portion at the top of the screen, followed by collapsible sections for affected components, design drawing references, and investigation recommendations. The terminal allows the user to select a section to open detailed views and to request related documents or diagrams from an external information providing device, such as a documentation server. When the user selects a diagram reference, the terminal requests the corresponding drawing file and displays it in a viewer. This interface design, in which the server pre-structures the information and the terminal performs targeted retrieval based on user selection, reduces unnecessary document downloads and improves communication efficiency.

The server further analyzes past accident data using the generative AI model to generate patterns of correlation between symptoms and impact ranges. The server constructs training pairs that include a description of observed symptoms and labels representing impacted components or subsystems. The server trains or fine-tunes the model to predict impact labels from symptom descriptions, again using a cross-entropy loss and backpropagation through the transformer network. The server stores the resulting mapping as a multi-label classification capability within the model or as a separate classifier model. In operation, when a new accident occurs, the server presents symptom descriptions to the classification capability and obtains probabilities over impact labels, thereby estimating which components and services are likely to be affected. The server includes these estimates as part of the structured design information, which improves accuracy and speed of impact analysis compared with conventional rule-based or manual approaches.

The server also generates recovery procedure candidates using learned patterns from past accidents. The server trains the generative AI model with sequences where the input includes structured accident data and the output includes recovery steps that historically led to resolution. The server includes constraints and formatting instructions in the training data, such as requiring numbered steps, precondition checks, and rollback instructions. This training causes the model to internalize a non-trivial mapping from multi-dimensional accident features to ordered action sequences. When a new accident is received, the server instructs the model, via an internal prompt sentence, to produce candidate recovery procedures conforming to a defined structure. This differs from simple automation of human-written manuals, because the model synthesizes procedures by combining learned patterns from multiple historical cases and by adapting step sequences to the specific combination of symptoms and configuration context.

The server further includes a module for analyzing an emotional state of the user. The server receives, from the terminal, features derived from user interaction behavior, such as typing speed, frequency of repeated queries, navigation patterns, and explicit feedback selections. The server may additionally analyze linguistic markers in user-entered prompt sentences or queries, such as the presence of stress-related expressions. The server uses a classifier model, which may be a smaller neural network or a statistical model, that outputs estimated emotional states such as “high stress,” “neutral,” or “low stress.” The server associates each emotional state with presentation policies that control the level of detail and expression format of the design information.

The server, when detecting a high-stress state, may send to the terminal a simplified summary, with prominent key actions and minimal technical detail, and hide advanced sections unless the user explicitly requests them. When detecting a neutral state, the server may present a balanced volume of technical detail. By adjusting the amount and style of information in this algorithmic manner, the server reduces cognitive load on users and decreases the probability of human errors under pressure. This adaptation is not achievable by static user interfaces and constitutes an improvement in human-computer interaction at the system level.

The described combination of data normalization, internal prompt sentence generation, domain-adapted large-scale language model training, structured post-processing, and adaptive presentation yields technical effects. The server reduces processing latency by automatically constructing optimized internal prompt sentences and by minimizing the number of model invocations through combined queries. The server improves accuracy of incident impact estimation and design information retrieval by mapping model outputs to internal identifiers and by enriching them with reliable database references. The server reduces communication load and memory usage by transmitting compact, structured summaries instead of entire document sets, and by retrieving full documents only when explicitly requested through the terminal. The server improves overall computing efficiency because the system orchestrates model computation, database access, and user interaction in a coordinated, non-conventional sequence that is specifically tailored to the technical problem of incident response in complex facilities.

In another embodiment, the server executes the large-scale language model as an external service, while retaining the same internal prompt generation, post-processing, and document-enrichment mechanisms. In still another embodiment, the server uses multiple generative AI models specialized for different subsystems, such as a model tuned for network infrastructure incidents and another tuned for application-level incidents, and selects a model based on an initial classification of the accident. In a further embodiment, the server logs internal prompt sentences and analysis result texts, associates them with actual resolution outcomes, and periodically retrains or fine-tunes the models and the prompt-generation rules based on these logs, thereby continuously improving system performance.

The terminal may vary as well. In one embodiment, the terminal is a control station with multiple displays that shows design information, live telemetry, and recovery procedures side by side. In another embodiment, the terminal is a handheld device used in the field, where network conditions may be unstable. In such a case, the server may compress the accident-response design information further and prioritize critical information to be transmitted first, thereby improving robustness of the system under constrained communication.

Through these embodiments, the server, the terminal, and the user cooperate in a technically specific manner. The server executes defined data structures, algorithms, and model-training procedures that transform raw accident inputs into structured, enriched, and adaptive outputs. The terminal presents such outputs in interaction-driven layouts, and the user uses the results to operate and restore real-world equipment and services. The overall configuration and operation go beyond abstract data manipulation or business-process automation and provide concrete improvements in computer technology, including improved processing speed, enhanced accuracy of incident diagnosis, optimized data management, and reduced communication overhead.

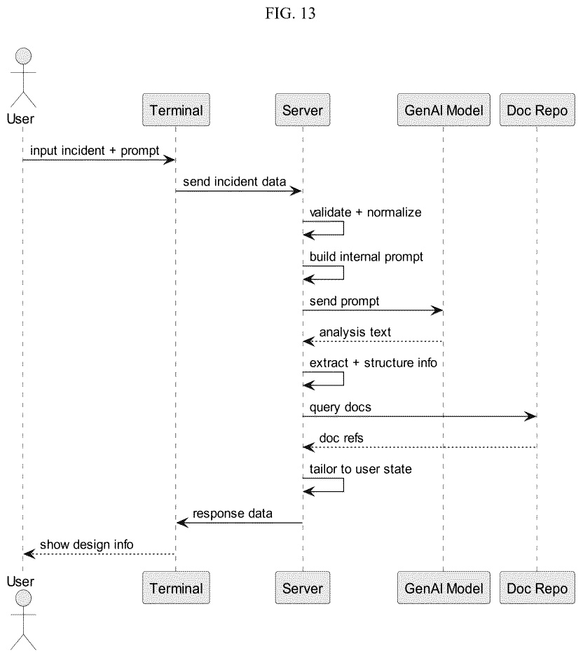

The following describes the processing flow using FIG. 13.

### Step 1

The terminal displays an accident input screen to the user.

The terminal provides input fields for date and time, location, impacted service or subsystem, symptom description, and error message.

The user enters accident details into these fields and optionally types a prompt sentence such as “Please provide design information related to the incident where the system returns ‘Error 503: Service Unavailable’ for the payment API.”

The user presses a submit button to finalize the input.

The input of this step is user-entered text and selected values; the output of this step is an in-memory representation of the accident information and the prompt sentence on the terminal.

### Step 2

The terminal converts the in-memory accident information into a structured request object.

The terminal encodes each field (for example, date and time, location, impact range, error message, and prompt sentence) into a predefined schema such as a key-value map.

The terminal serializes this schema into a structured format, such as a JSON string, and attaches metadata including terminal identifier and user identifier.

The terminal opens a secure communication channel to the server using a protocol such as HTTPS and transmits the serialized request as the body of an HTTP request.

The input of this step is the in-memory representation from Step 1; the output of this step is a structured network message sent toward the server.

### Step 3

The server receives the structured network message through the network interface.

The server parses the HTTP headers and the serialized body to reconstruct the structured request object in memory.

The server validates required fields, checks that the time format is parsable, confirms that the location is non-empty, and verifies that an error message or symptom description is present. The server rejects invalid requests by generating an error response, or accepts valid requests by storing the structured accident information in a temporary data structure.

The input of this step is the serialized network message from the terminal; the output of this step is a validated, structured accident record in the server's memory, or an error response returned to the terminal.

### Step 4

The server normalizes the structured accident record into canonical internal representations. The server converts the time string into a unified time format and a numerical timestamp value.

The server maps the location text and impacted service names to internal identifiers using lookup tables stored in a configuration database.

The server classifies the impact range and error category by applying rule-based classifiers and pattern-matching algorithms to the error messages and symptom descriptions.

The server constructs a normalized accident object that explicitly contains normalized time, location identifiers, impact categories, and error categories.

The input of this step is the validated structured accident record from Step 3; the output of this step is a normalized accident object ready for prompt construction.

### Step 5

The server generates an internal prompt sentence based on the normalized accident object. The server selects a template from a template library depending on the impact category and subsystem type (for example, network, application, or database).

The server inserts normalized fields, such as time, subsystem identifier, impact range, and error description, into placeholder positions within the template.

The server appends context information, including system architecture identifiers, model version numbers, and configuration snapshot identifiers, to the textual prompt, thereby creating a composite prompt sentence.

The server stores the internal prompt sentence in association with the normalized accident object in memory.

The input of this step is the normalized accident object from Step 4; the output of this step is an internal prompt sentence formatted as natural language text.

### Step 6

The server prepares model input data for a generative AI model based on the internal prompt sentence.

The server tokenizes the internal prompt sentence using a tokenizer that converts substrings into integer token IDs.

The server constructs a sequence of token IDs and attaches model parameters such as maximum output length and temperature.

The server encapsulates the token sequence and parameter values into a model request structure.

The input of this step is the internal prompt sentence from Step 5; the output of this step is a model request structure suitable for input to the generative AI model.

### Step 7

The server executes inference on the generative AI model by supplying the model request structure.

When the model runs locally, the server loads the token sequence into GPU or CPU memory, performs transformer-based computations including multi-head self-attention and feed-forward network operations, and generates output token probabilities for each decoding step. When the model runs as an external service, the server transmits the model request structure via a secure API and receives an output token sequence in a response.

The server decodes the output token sequence into a natural language analysis result text. The input of this step is the model request structure from Step 6; the output of this step is analysis result text generated by the generative AI model.

### Step 8

The server interprets the analysis result text to extract structured technical information. The server applies a text parsing module that performs tokenization, part-of-speech tagging, and named entity recognition to identify component names, configuration items, and failure scenarios mentioned in the text.

The server matches recognized entities against internal dictionaries and mapping tables to obtain internal identifiers for components, services, configuration parameters, and documents.

The server constructs an intermediate structured representation that lists components, connection relationships, configuration items, and suggested actions derived from the analysis result text.

The input of this step is the analysis result text from Step 7; the output of this step is an intermediate structured representation of design-related information.

### Step 9

The server generates structured design information from the intermediate representation. The server arranges extracted components into a hierarchy or graph that reflects their functional roles and connection relationships.

The server groups configuration items by component and annotates them with current values retrieved from the configuration database.

The server organizes suggested actions into ordered lists with labels such as “investigation step” or “recovery step.”

The server stores the structured design information as a composite object including sections for summary, affected components, configuration items, and recommended procedures.

The input of this step is the intermediate structured representation from Step 8; the output of this step is a structured design information object.

### Step 10

The server enriches the structured design information by querying external repositories.

The server extracts component identifiers, document identifiers, and configuration keys from the structured design information and generates search queries for a document management device or information retrieval device.

The server transmits the queries, receives search results including document metadata and diagram references, and selects the most relevant documents based on ranking criteria such as matching scores and modification dates.

The server attaches document reference information, including titles, identifiers, and access paths, to the appropriate sections of the structured design information.

The input of this step is the structured design information object from Step 9; the output of this step is enriched accident-response design information containing both structured technical data and document references.

### Step 11

The server adapts the accident-response design information to the user's emotional state. The server reads recent user input content and operation history received from the terminal, such as query frequency, navigation patterns, and response times.

The server applies an emotional-state classifier that computes features from the interaction data and outputs a state label such as high stress, neutral, or low stress.

The server adjusts the level of detail in the accident-response design information by selecting which sections to highlight, summarize, or hide by default, and modifies the expression format by choosing between detailed technical explanations and concise bullet lists.

The server generates a presentation-specific representation of the accident-response design information tailored to the detected emotional state.

The input of this step is the enriched accident-response design information from Step 10 and user interaction data; the output of this step is a tailored presentation representation.

### Step 12

The server formats the tailored presentation representation into a response message for the terminal.

The server organizes content into logical display regions such as a summary region, an affected component region, a design document reference region, and a recommended action region.

The server compresses the representation if necessary to reduce message size and encodes it into a structured format suitable for transmission.

The server sends the formatted response message to the terminal via the secure communication channel.

The input of this step is the tailored presentation representation from Step 11; the output of this step is a structured response message transmitted to the terminal.

### Step 13

The terminal receives the response message from the server.

The terminal parses the structured format and reconstructs display-region objects in memory. The terminal renders the summary, component list, diagram references, and recommended procedures in separate visual areas on the display device, using controls such as tabs, collapsible panels, and buttons.

The terminal sends additional requests to an external information providing device when the user selects a document or diagram reference, and displays the retrieved document or diagram.

The input of this step is the structured response message from Step 12; the output of this step is the visual presentation of accident-response design information on the terminal display.

### Step 14

The user reviews the displayed accident-response design information on the terminal.

The user examines the summary to understand the overall situation, inspects the affected components and configuration items, and reads the recommended investigation and recovery steps.

The user selects document references to open detailed design documents or diagrams and may perform additional actions such as annotating steps or initiating maintenance operations according to the guidance.

The input of this step is the visual presentation produced by the terminal; the output of this step is user decisions and subsequent actions based on the provided design information.

### Application Example 2

Description follows regarding a flow of the specific processing in an Application Example 2. The units of the system described below are implemented by the data processing device 12 and the smart device 14. The data processing device 12 is called a “server” and the smart device 14 is called a “terminal”.

In complex technical environments such as transportation systems, industrial facilities, and information infrastructures, operators must respond to abnormal events and incidents under severe time pressure while interpreting heterogeneous data streams, including sensor measurements, image data, log records, and design documentation. Conventional incident-response systems rely on static rule sets or pre-defined workflows that are unable to flexibly combine current multi-modal data, historical patterns, and detailed design or specification information. As a result, such systems often fail to accurately estimate an impact range or to generate context-appropriate recovery procedures in real time. Furthermore, conventional systems typically treat the human operator as a passive recipient of alerts and fixed instructions. These systems do not adapt their analytical behavior or their presentation format based on a current emotional state of the operator. When the operator is under high cognitive load or stress, non-adaptive systems may deliver information that is either too terse or too complex, increasing the likelihood of operational errors and delaying recovery. From a computer-technology perspective, existing architectures lack an integrated processing pipeline that (i) constructs composite feature data from heterogeneous inputs, (ii) dynamically generates prompt sentences for a generative AI model on the basis of prediction results and internal technical context, (iii) controls the behavior of the generative AI model via machine-interpretable metadata and control signals, and (iv) uses feedback and incident histories to continuously improve the underlying models and system behavior.

Accordingly, there is a need for an improved computer-implemented system that enhances the functioning of computing components themselves, by providing specific data structures, control flows, and model interactions that allow a processor to: preprocess and integrate numerical, visual, and textual data into composite feature data; use prediction models to compute impact ranges and candidate causes; automatically synthesize machine-generated prompt sentences that encode technical context and safety constraints for a generative AI model; adjust both prompts and generated natural-language responses on the basis of emotion analysis; and log structured interaction histories for subsequent model retraining. Such a system should reduce processing latency, improve the technical accuracy and relevance of generated recovery procedures, and adapt the presentation and content of system outputs to the current operational and emotional context of the user, thereby providing a concrete improvement in computer technology used for incident analysis and response.

The specific processing by the specific processing unit 290 of the data processing device 12 in Application Example 2 is realized by the following means.

The present invention provides a server comprising a processor configured to preprocess and fine-tune a generative AI model based on a large language model using document data including design information, specification information, configuration information, and incident information, to receive numerical data and image data from detection apparatuses and text data including an event description, to generate composite feature data by time-series alignment, missing-value completion, normalization, feature extraction, and integration, to execute a prediction model learned on the basis of past events in order to estimate an impact range and candidate causes, to automatically construct a prompt sentence including metadata representing at least the impact range, the candidate causes, target structural elements, and safety rules and to input the prompt sentence into the generative AI model, to obtain from the generative AI model a natural-language response including an explanation of an incident and recovery procedures, to analyze an emotional state of a user on the basis of voice, image, or operation data and adjust at least one of a level of detail, an expression style, and a presentation method of the prompt sentence and the natural-language response according to the emotional state, to control presentation devices so as to visualize the impact range on at least one of a map and a facility layout and to present the recovery procedures in a stepwise format while accepting additional user input as further prompt sentences for iterative response generation, and to record incident data, the composite feature data, prediction results, prompt sentences, natural-language responses, and user feedback as a history and to perform retraining or updating of the generative AI model and the prediction model on the basis of the history. This enables the computing system to perform technically improved incident analysis and response in that the processor itself is configured with specific data processing pipelines, prompt-generation mechanisms, model-control interfaces, and adaptive presentation logic that reduce processing time, increase the accuracy and contextual relevance of generated recovery procedures, and dynamically tailor system behavior to heterogeneous multi-modal inputs and the user's emotional state, thereby enhancing the functionality and efficiency of the underlying computer technology.

The term “generative AI model” refers to a machine learning model, typically based on a large language model architecture, that is trained to generate new data, including natural-language text, in response to input data such as prompt sentences and contextual information.

The term “large language model” refers to a parameterized machine learning model trained on a large corpus of text data to perform natural-language understanding and generation by computing probability distributions over sequences of tokens.

The term “document data” refers to digital data representing one or more documents, including but not limited to design documents, specification documents, configuration documents, and incident reports, stored in formats such as text files, markup files, or page description files.

The term “design information” refers to technical information describing a structure, function, or behavior of a system, component, or apparatus, including diagrams, parameters, and relationships between constituent elements.

The term “specification information” refers to technical information describing required functions, performance characteristics, constraints, and operational conditions of a system, component, or apparatus.

The term “configuration information” refers to information indicating constituent elements of a system, component, or apparatus and relationships among the constituent elements, including topological, hierarchical, or dependency relations.

The term “incident information” refers to information describing an occurrence of an abnormal event, fault, accident, or failure, including time, location, affected elements, observed symptoms, and operator notes.

The term “numerical data” refers to digital representations of quantitative values obtained from sensors, meters, or monitoring systems, including time-series measurements such as temperature, pressure, speed, or position.

The term “image data” refers to digital data representing visual information, including still images and video frames captured by imaging devices such as cameras or optical sensors.

The term “detection mechanism” refers to hardware and software that acquire measurement data or state information from a physical environment or system, including sensors, controllers, and associated interfaces.

The term “text data” refers to sequences of characters or tokens representing human-readable information, including user-authored descriptions, log messages, and labels.

The term “event description” refers to text data input by a user or generated by a system that verbally describes circumstances, symptoms, or context of an incident.

The term “composite feature data” refers to a data structure in which features derived from heterogeneous sources, including numerical data, image data, and text data, are integrated into a unified representation suitable for input to a machine learning model.

The term “time-series alignment” refers to processing that adjusts timestamps and sampling points of multiple data streams so that measurements from different sources correspond to common time intervals or reference times.

The term “missing-value completion” refers to processing that replaces absent or incomplete data entries with estimated or predetermined values according to rules or statistical methods. The term “normalization” refers to processing that transforms data values into a standardized scale or distribution to improve numerical stability or comparability for subsequent computation.

The term “feature extraction” refers to processing that derives informative numerical or symbolic attributes from raw data, including operations such as filtering, transformation, and pattern detection.

The term “integration” refers to processing that combines features from multiple data sources or modalities into a single data structure, such as a vector, tensor, or record, for joint analysis. The term “prediction model” refers to a trained machine learning model configured to compute an output such as an impact range or cause estimate from input feature data, based on patterns learned from past data.

The term “impact range” refers to a set of elements, regions, or systems that are predicted or determined to be affected by an incident, including spatial areas, logical subsystems, or service domains.

The term “candidate causes” refers to one or more hypothesized reasons for an incident, derived from correlation between observed data and previously learned patterns, and represented as structured information or text.

The term “prompt sentence” refers to text data supplied to a generative AI model that specifies a task, context, or question and guides the model to generate an appropriate natural-language response.

The term “metadata” refers to structured information that describes properties of data or context, including impact ranges, candidate causes, target elements, and safety rules, and that can be inserted into a prompt sentence or stored with other data.

The term “target structural elements” refers to specific components, subsystems, or regions within a larger system that are indicated as being relevant to an incident, an impact range, or a recovery procedure.

The term “safety rules” refers to predefined constraints or policies that specify prohibited operations, required precautions, escalation conditions, or other safety-related requirements during incident handling.

The term “natural-language response” refers to output text generated by a generative AI model using a human language, such as instructions, explanations, or summaries, in response to a prompt sentence and context.

The term “emotional state” refers to a condition of a user's affect or mood, such as stress, calmness, anxiety, or confusion, inferred from observable data including voice characteristics, facial expressions, or interaction patterns.

The term “voice data” refers to audio signals or digital representations of speech produced by a user and captured by an audio input device.

The term “image data of the user” refers to visual data representing the user, including facial images or video sequences captured by an imaging device.

The term “operation data” refers to information derived from a user's interactions with an interface, including keystrokes, pointer movements, touch patterns, and response times.

The term “level of detail” refers to a degree of granularity or amount of information included in a prompt sentence or a natural-language response, such as the number of steps, substeps, or technical parameters.

The term “expression style” refers to characteristics of wording and tone in a natural-language response, including technicality, formality, and use of supportive or neutral language.

The term “presentation method” refers to a mode or format in which information is delivered to a user, including text layout, graphical views, audio narration, and interaction elements. The term “presentation devices” refers to hardware configured to output information to a user, including display devices and audio output devices.

The term “map” refers to a visual representation of a physical or logical area, such as a geographic layout or a network topology, on which an impact range can be indicated. The term “facility layout” refers to a schematic or plan view representing physical arrangement of spaces, equipment, or infrastructure elements within an installation.

The term “stepwise format” refers to a presentation in which recovery procedures are divided into ordered steps or stages that can be followed sequentially by a user.

The term “additional input” refers to subsequent user-provided data, including further prompt sentences, clarifications, or questions, supplied after an initial response has been presented. The term “history” refers to stored records of past system interactions, including incident data, composite feature data, prediction results, prompt sentences, natural-language responses, and user feedback, used for analysis or retraining.

The term “retraining” refers to a process of further training a machine learning model using additional or updated data so as to adjust model parameters and improve performance.

The term “updating” refers to a process of changing parameters, configurations, or versions of a generative AI model or prediction model, including retraining, fine-tuning, or model replacement.

In one embodiment, a server, a terminal, and a user cooperate to implement the invention. The server comprises at least one processor, a memory, a non-transitory storage device, and a network interface. The terminal comprises at least one processor, a display device and/or an audio output device, an input device such as a touchscreen or keyboard, and optionally one or more sensors including a camera, a microphone, and other environmental sensors. The user operates the terminal and interacts with the server via a communication network.

The server uses software components including an operating system, a database management system, a model serving framework, and machine learning libraries such as a deep learning framework and a natural language processing library. The server stores a generative AI model based on a large language model architecture, such as a Transformer-type neural network with self-attention layers, multiple encoder/decoder blocks, and a large number of parameters. The server also stores one or more prediction models implemented as neural networks (for example, feedforward networks or recurrent networks) trained to estimate impact ranges and candidate causes from composite feature data.

The server prepares training data by collecting document data that include design information, specification information, configuration information, and incident information. The server obtains such document data from structured and unstructured repositories, including relational databases and file storage systems. The server converts various document formats (for example, page description formats, markup formats, and plain text formats) into normalized text sequences. The server uses a natural language processing library to perform tokenization, sentence segmentation, part-of-speech tagging, and entity recognition on the document data. The server creates data structures in which each document is represented as a sequence of tokens aligned with metadata fields such as component identifiers, parameter labels, and section headings.

The server uses the processed document data to fine-tune the generative AI model. The server constructs input-output training pairs by selecting passages from the document data and associating them with synthetic or human-authored questions and answers about design, specification, and configuration. The server uses a supervised learning method in which the generative AI model receives token sequences that encode a prompt sentence and associated context and is trained to output a target token sequence representing a desired answer. The server defines an objective function such as cross-entropy loss over token probabilities and minimizes the loss by adjusting the weights of the neural network via gradient-descent-based optimization. The server may perform data augmentation by rephrasing questions, shuffling context order, or masking portions of the context, thereby improving the model's robustness. This fine-tuning process configures the generative AI model to internalize domain-specific structural relationships, such as which components depend on which subsystems, or which parameters define a safe operating range.

The server also trains a prediction model to estimate impact ranges and candidate causes. The server constructs training samples from historical incident records, each sample including composite feature data as input and ground-truth labels for impacted regions and root causes as output. The server designs the prediction model as a multi-layer neural network that receives a fixed-length feature vector and outputs probability distributions over possible impact zones and cause categories. The server defines a multi-task loss function combining, for example, a categorical cross-entropy term for impact classification and a categorical cross-entropy term for cause classification. The server updates model weights by backpropagating gradients computed from this loss, thereby learning mappings from observed feature patterns to impact and cause estimates. This training process creates a technical improvement by enabling the server to perform real-time, multi-modal inference that is not feasible with fixed rule engines.

The terminal acquires incident-related data in real time. The terminal reads numerical data from connected detection mechanisms, such as sensors measuring speed, acceleration, temperature, pressure, position, or environmental conditions. The terminal captures image data or video data from one or more cameras monitoring vehicles, equipment, or facilities. The terminal optionally records audio data and user interaction data, including keypress timings and pointer movements. The terminal associates each item of numerical, visual, and interaction data with time stamps and unique identifiers, forming time-indexed data structures that can be transmitted to the server.

The server receives incident-related data from the terminal through the network interface. The server stores raw sensor streams and image data into a time-series storage subsystem and an object storage subsystem. The server performs preprocessing on numerical data by aligning measurements from different sources based on their timestamps, interpolating missing values, and applying digital filtering (for example, smoothing or band-pass filtering) to remove noise. The server transforms raw measurements into normalized feature values by applying scaling or standardization. By performing these numerical operations, the server reduces noise and heterogeneity, which improves the numerical stability and accuracy of subsequent neural network inference.

The server preprocesses image data by decoding video streams into individual frames at regular intervals, resizing the frames, and converting them into tensors. The server applies a visual feature extractor such as a convolutional neural network to each frame to detect objects (for example, vehicles, obstacles, machines) and events (for example, collisions, smoke, blocking). The server maps the probabilities and bounding boxes output by the visual feature extractor into feature vectors that describe the scene at each time point. The server aligns the extracted visual features with the time-aligned numerical data, resulting in a combined multi-modal representation.

The server further preprocesses text data. The user may provide an event description as free-form text via the terminal, such as “The vehicle suddenly stopped after detecting an obstacle” or “The server is not responding and the network connection is unstable.” The server uses a natural language processing library to tokenize the description, identify key phrases, and map them to known component names or error categories. The server encodes these textual features as numerical vectors, for example by using an embedding layer or term-frequency features. The server integrates numerical, image, and text features into composite feature data, which may be implemented as a fixed-length vector, a tensor with modality-specific segments, or a structured record with clearly defined fields. This specific multi-modal integration pipeline constitutes a technical data structure that enables efficient processing by the prediction model and the generative AI model.

The server uses the prediction model to estimate an impact range and candidate causes from the composite feature data. The server performs a forward pass of the neural network prediction model using matrix multiplications and non-linear activation functions to compute probabilities associated with possible impact zones, affected components, and probable root causes. The server interprets these outputs by applying thresholds or ranking operations and creates data structures that list the most likely impacted subsystems, spatial areas, and cause hypotheses together with associated confidence scores. The server thereby transforms raw and noisy sensor and visual signals into structured, machine-interpretable diagnostics in a way that improves accuracy and speed compared to manual analysis or simple heuristic rules. The server constructs a prompt sentence for the generative AI model based on the prediction results and internal context. The server retrieves relevant design, specification, and configuration excerpts from the document data based on the impacted components and cause hypotheses. The server assembles a prompt sentence that includes: a description of the current symptoms; a summary of the predicted impact range and candidate causes; excerpts of technical documentation; and metadata such as safety rules and identifiers of target elements. The server embeds control information in the prompt sentence that instructs the generative AI model regarding a required response style, such as “provide a detailed explanation” or “provide a concise summary.” This prompt construction process is non-trivial and uses specific rules for ordering context segments, inserting metadata tags, and delimiting sections so that the generative AI model can parse and attend to critical information efficiently. By encoding prediction outputs and safety constraints directly into the prompt sentence, the server improves the relevance and safety compliance of generated text, thereby enhancing the functionality of the underlying model.

The server adapts the prompt sentence and the generated output based on the user's emotional state. The terminal may capture voice data and image data of the user while the user interacts with the system. The server, or in some embodiments the terminal, executes an emotion analysis model that computes features such as pitch variation, speech rate, facial expression metrics, and interaction latency. The emotion analysis model may be implemented as a neural network trained on labeled emotional data. The server interprets the model output to determine whether the user is stressed, calm, confused, or relaxed. When the user is stressed, the server modifies the prompt sentence by adding phrases that request the generative AI model to use supportive language and to break procedures into smaller steps. When the user is relaxed or expert, the server instructs the generative AI model to suppress redundant explanations and provide a compact answer. This control mechanism causes the computer system to adapt its internal processing, not merely its display, because the behavior of the generative AI model is influenced by structured control tokens that alter its attention and decoding patterns.

The server invokes the generative AI model using the constructed prompt sentence. The server sends the tokenized prompt to a model serving component that performs a forward pass through the Transformer architecture. The model processes the prompt using self-attention operations that compute weighted combinations of token embeddings, applying learned projection matrices that were fine-tuned on domain-specific data. The server decodes the output tokens by applying a generation algorithm such as beam search or sampling with constraints, thereby generating a natural-language response that describes the probable cause, detailed impact range, and recommended recovery procedures. Because the model has been fine-tuned with domain-specific examples and receives structured context via the prompt, the generated response can incorporate precise parameter values, component identifiers, and safety steps, which exceeds the capabilities of general-purpose models or simple template engines.

The server post-processes the natural-language response to extract structured recovery steps and to enforce safety rules. The server uses pattern recognition or parsing techniques to identify step numbers, target regions, and action verbs in the response. The server compares recommended actions against stored safety rules and, when a recommendation conflicts with a safety rule, flags the conflict, adjusts wording, or requests confirmation. The server converts the parsed steps into a structured representation, such as an ordered list of step objects containing fields for description, target element, required tools, expected duration, and risk level. This structure enables the terminal to present steps in an interactive user interface and to track completion.

The terminal presents the impact range and recovery procedures to the user. The terminal receives structured data and natural-language text from the server and renders them using graphical and/or audio output. The terminal draws the predicted impact range on a map or facility layout, using colors and symbols to indicate severity and affected zones. The terminal displays the recovery procedures as a list of steps, optionally with controls for marking completion or requesting further detail. The terminal may present additional explanatory text or diagrams when the user taps or selects a step. The terminal can also narrate the procedures using speech synthesis, with speech rate and tone adjusted according to the estimated emotional state.

The user interacts with the terminal to execute the recovery procedures. The user views the impact visualization, identifies the affected area or equipment, and performs physical operations such as shutting down a line, restarting a controller, or inspecting a sensor. The user marks completion of steps or enters follow-up questions as additional prompt sentences. Example prompt sentences include “Explain step 2 in more detail for a non-expert operator” and “Show the detailed design specification of the front sensor module involved in this accident.” The terminal forwards these prompt sentences to the server, which reconstructs context, updates the prompt sentence, and causes the generative AI model to generate further clarifications. This interactive loop allows the system to adaptively refine explanations and procedures while maintaining consistent internal data structures.

The server continuously logs data for technical improvement. The server records raw sensor and image data, composite feature data, prediction outputs, constructed prompt sentences, generated responses, user actions, and user feedback into a history repository. The server periodically analyzes this history to identify patterns where prediction or generation was inaccurate or where user feedback indicated confusion. The server uses such cases to create new training samples for both the prediction model and the generative AI model. The server then performs retraining or incremental fine-tuning, using a loss function that may combine prediction error, response quality metrics, and safety-rule compliance metrics. This closed feedback loop results in improved model parameters that reduce future error rates, shorten processing time by enabling more confident early decisions, and improve the stability and efficiency of the computing system.

In another embodiment, the server and the terminal are deployed in an autonomous vehicle environment. The terminal is implemented as an in-vehicle computing unit that collects vehicle-mounted sensor data and camera images. The server resides in a remote center and receives incident data from multiple vehicles. When an accident occurs, the terminal transmits high-priority compressed sensor snapshots and key video frames, thereby reducing communication load while preserving essential features. The server performs the same composite feature generation, prediction, prompt construction, and generative response operations as described above. The server then sends concise, prioritized recovery and safety instructions back to the terminal, which displays messages to the driver such as “You are in a safe position on the shoulder. Take a deep breath and stay calm. Follow these steps: (1) Turn on the hazard lights. (2) Exit the vehicle only if the surroundings are safe. (3) Place the warning triangle 50 meters behind the vehicle.” The server may generate such text from a prompt sentence like “Based on the current accident on the highway, predict the impact range and propose detailed recovery steps with supportive messages for a highly stressed driver.” This embodiment demonstrates how the claimed system directly controls user behavior in a physical environment and improves safety by combining real-time prediction, adaptive generation, and emotion-aware control.

In yet another embodiment, the system is applied to an industrial facility. The terminal may take the form of smart glasses or a tablet used by maintenance personnel. When a fire or critical malfunction occurs, the terminal sends sensor data and video from the affected area to the server. The server predicts the impact range over production lines and warehouses and generates recovery procedures. An example prompt sentence for the generative AI model is “Predict the impact range when a fire occurs at factory A and propose the optimal recovery steps.” The server returns both a map showing at-risk zones and a sequence of actions such as shutting down specific lines, isolating power, and rerouting production. The terminal overlays this information on the operator's field of view, guiding the operator to specific equipment. Because the server uses trained neural networks and composite feature data rather than fixed scripts, the system can adapt to unanticipated patterns and still produce coherent, technically sound guidance.

The described embodiments provide technical advantages beyond mere automation of human decision making. The server defines explicit, non-conventional data structures (composite feature data with integrated multi-modal features, structured prompt sentences with embedded metadata, structured recovery step lists) and uses specific neural network architectures and training methods for both prediction and generation. The integration of prediction outputs, context retrieval, emotion analysis, and generative control into a coordinated pipeline improves the speed and accuracy of incident analysis, reduces communication load by transmitting only processed and compressed features when necessary, enhances data management by recording structured histories, and decreases operational errors by tailoring information delivery to the user's emotional and situational context. These technical effects arise from the particular arrangement and interoperation of the server, the terminal, the generative AI model, the prediction model, and the emotion analysis model, and not from generic business logic or human workflow automation.

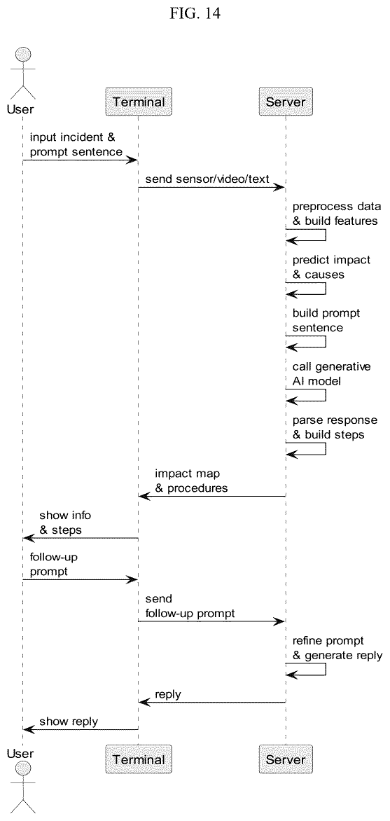

The following describes the processing flow using FIG. 14.

### Step 1

The server collects and preprocesses document data.

The server receives as input various document files that include design information, specification information, configuration information, and incident information from one or more storage systems. The server parses the input files, converts them into plain text, and applies natural language processing to segment the text into sentences and tokens. The server then performs data cleaning, such as removing headers, footers, and duplicate sections, and maps technical terms to internal identifiers. The server outputs normalized document records in which each passage is stored together with metadata such as component identifiers, parameter names, and document section types.

### Step 2

The server fine-tunes a generative AI model on the document records.

The server uses as input the normalized document records from Step 1 and a pre-trained large language model that serves as the base of the generative AI model. The server generates training pairs by constructing prompt sentences from questions about the design, specification, and configuration, and by associating each prompt sentence with an answer extracted from the corresponding document passage. The server performs data operations including tokenization of the prompt-answer pairs, calculation of a loss function over token prediction errors, and gradient-based weight updates across the neural network layers. The server outputs a fine-tuned generative AI model that encodes domain-specific knowledge of the target systems.

### Step 3

The server trains a prediction model for impact and cause estimation.

The server receives as input historical incident data, including composite feature data derived from past sensor readings, images, and text descriptions, together with ground-truth labels for impact ranges and causes. The server performs feature normalization, shuffling, and batching to prepare the training data. The server applies a supervised learning algorithm to a neural network prediction model, computing forward passes to generate predicted labels, computing a multi-task loss, and propagating gradients backward to update weights. The server outputs a trained prediction model capable of estimating impact ranges and candidate causes from new composite feature data.

### Step 4

The terminal acquires current incident data from sensors and user input.

The terminal receives as input raw signals from connected detection mechanisms such as numerical sensor streams, camera images or video frames, and optional audio signals. The terminal also receives a text description entered by the user, for example “The vehicle suddenly stopped after detecting an obstacle” or “The server is not responding and the network connection is unstable.” The terminal timestamps each input, tags it with a source identifier, and optionally compresses image or video frames. The terminal outputs structured incident packets that bundle the numerical data, image data, audio data, and text description, and transmits the packets to the server.

### Step 5

The server ingests and aligns the incident data.

The server receives as input the structured incident packets from the terminal. The server writes raw sensor data into a time-series store and image data into an object store, preserving timestamps and identifiers. The server performs numerical operations to align different sensor streams in time, interpolates missing measurements, and applies noise-reduction filters. The server decodes image data into frames and associates each frame with the corresponding sensor time window. The server outputs synchronized numerical and visual data series, each linked by a unified time axis.

### Step 6

The server extracts numerical, visual, and textual features.

The server uses as input the synchronized numerical series, visual frames, and the user's text description. For numerical data, the server computes derived features such as rates of change, moving averages, and threshold exceedances. For visual data, the server applies a convolutional neural network to each frame to detect objects and events, and converts detection results into feature vectors that describe, for example, object types and positions. For textual data, the server tokenizes the description, identifies key phrases, and encodes them as numerical embeddings. The server combines these features into composite feature data, outputting a unified feature representation suitable for input to the prediction model and the generative AI model.

### Step 7

The server estimates the impact range and candidate causes.

The server receives as input the composite feature data from Step 6 and the trained prediction model from Step 3. The server performs a forward pass through the prediction model, executing matrix multiplications and non-linear activations to compute probability distributions over possible impacted regions and cause categories. The server then applies a decision rule, such as selecting labels whose probabilities exceed a threshold or ranking labels by probability. The server outputs a structured impact-and-cause record that lists predicted impact ranges, candidate causes, and confidence scores.

### Step 8

The server retrieves relevant technical context.

The server takes as input the impact-and-cause record and the normalized document records from Step 1. The server performs queries against the document store using component identifiers, subsystem names, and parameter labels extracted from the impact-and-cause record. The server retrieves passages that describe the structure, specifications, and configuration of impacted elements. The server organizes the retrieved passages by relevance and priority and outputs a context bundle that includes design excerpts, specification limits, configuration diagrams, and any associated safety rules.

### Step 9

The server performs emotion analysis for adaptive control.

The server receives as input user-related data from the terminal, such as voice recordings, facial images, and interaction metrics, and optionally an emotion analysis model that has been pre-trained. The server extracts features such as pitch variance, speech speed, facial expression indicators, and response latency. The server feeds these features into the emotion analysis model and computes an emotional state classification, for example stressed, calm, or confused, together with confidence scores. The server outputs an emotion state record that describes the current emotional condition of the user.

### Step 10

The server constructs a prompt sentence for the generative AI model.

The server uses as input the impact-and-cause record, the context bundle, and the emotion state record. The server generates textual segments describing the current symptoms, predicted impact range, and candidate causes. The server inserts excerpts from the context bundle to provide technical background and safety constraints. The server adds metadata tokens or phrases specifying control information, such as a request for “detailed explanation” when the user is stressed or for “concise summary” when the user is relaxed. The server concatenates these segments into a structured prompt sentence. The server outputs the prompt sentence as a single text string ready to be tokenized for the generative AI model.

### Step 11

The server generates a natural-language response using the generative AI model.

The server receives as input the prompt sentence from Step 10 and the fine-tuned generative AI model from Step 2. The server tokenizes the prompt sentence and feeds the tokens into the Transformer architecture, where self-attention layers compute context-dependent token representations. The server executes a decoding algorithm that iteratively predicts the next token based on the current context and accumulated output, constrained by the control information embedded in the prompt sentence. The server continues generation until an end condition is met, such as reaching an end-of-sequence token. The server outputs a natural-language response that explains the probable cause, describes the impact range, and proposes step-by-step recovery procedures.

### Step 12

The server parses and structures the generated response.

The server takes as input the natural-language response generated in Step 11. The server applies pattern matching, syntactic parsing, or rule-based extraction to identify step numbers, action verbs, target regions, and warning phrases. The server checks each extracted action against stored safety rules to detect prohibited or risky operations. The server then builds a structured recovery-procedure list in which each step is represented as an object with fields such as description, target element, priority, and risk level. The server outputs both the original natural-language response and the structured recovery-procedure list.

### Step 13

The terminal presents impact information and recovery procedures.

The terminal receives as input the natural-language response, the structured recovery-procedure list, and the impact-and-cause record. The terminal renders a visualization of the impact range on an appropriate background such as a map or facility layout, using colors and symbols derived from the impact-and-cause record. The terminal displays the recovery-procedure list as an ordered set of steps, with user interface elements for expanding details, marking completion, or requesting further explanations. If audio output is available, the terminal converts the text into speech and plays it to the user. The terminal outputs a user interface state that reflects the current presentation and any user selections.

### Step 14

The terminal adapts the presentation based on the emotion state.

The terminal uses as input the emotion state record received from the server or computed locally. The terminal adjusts visual parameters such as font size, contrast, and amount of on-screen text, and adjusts audio parameters such as speech rate and tone. For a stressed user, the terminal may enlarge critical warnings, slow down the speech, and highlight one step at a time. For a relaxed or expert user, the terminal may condense the display and show more technical details per screen. The terminal outputs an updated presentation that matches the user's emotional condition and reduces cognitive load.

### Step 15

The user executes actions and issues follow-up prompt sentences.

The user receives as input the impact visualization and recovery procedures displayed or spoken by the terminal. The user performs concrete operations in the physical environment, such as stopping equipment, checking sensors, or evacuating areas, and then interacts with the terminal to mark steps as completed. When additional clarification is needed, the user enters further questions as prompt sentences, for example “Explain step 2 in more detail for a non-expert operator” or “Show the detailed design specification of the front sensor module involved in this accident.” The user supplies these prompt sentences via text input or speech, and the terminal captures them as new input. The terminal outputs updated interaction data and follow-up prompt sentences to the server.

### Step 16

The server performs iterative clarification and logging.

The server receives as input the follow-up prompt sentences and the current context, including which steps have been completed and the existing impact-and-cause record. The server augments the new prompt sentences with the current context to form refined prompt sentences and again invokes the generative AI model to generate additional responses. In parallel, the server logs data including incident packets, composite feature data, prediction outputs, prompt sentences, natural-language responses, and user feedback into a history store. The server outputs updated explanations for the user and accumulated history records that can be used later for retraining and improvement of the generative AI model and the prediction model.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Moreover, although the processing by the data processing system 10 described above was executed by the specific processing unit 290 of the data processing device 12 or by the control unit 46A of the smart device 14, the processing may be executed by a specific processing unit 290 of the data processing device 12 and a control unit 46A of the smart device 14. Moreover, the specific processing unit 290 of the data processing device 12 acquires and collects information needed for processing from the smart device 14 or from an external device or the like, and the smart device 14 acquires and collects information needed for processing from the data processing device 12 or from an external device or the like.

For example, a collection unit is implemented by the control unit 46A of the smart device 14 and/or by the specific processing unit 290 of the data processing device 12. For example, an acquisition unit acquires number-of-steps data using the camera 42 and/or the communication I/F 44 of the smart device 14, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the output device 40 of the smart device 14 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the smart device 14.

### Second Exemplary Embodiment

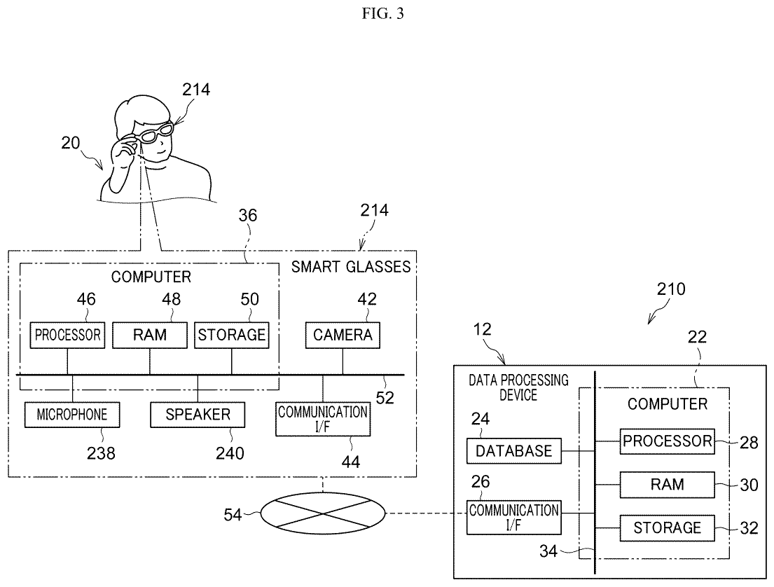

FIG. 3 illustrates an example of a configuration of a data processing system 210 according to a second exemplary embodiment.

As illustrated in FIG. 3, the data processing system 210 includes a data processing device 12 and smart glasses 214. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The smart glasses 214 include a computer 36, a microphone 238, a speaker 240, a camera 42, and a communication I/F 44. The computer 36 includes a processor 46, RAM 48, and storage 50. The processor 46, the RAM 48, and the storage 50 are connected to a bus 52. The microphone 238, the speaker 240, the camera 42, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the user 20 (for example, an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

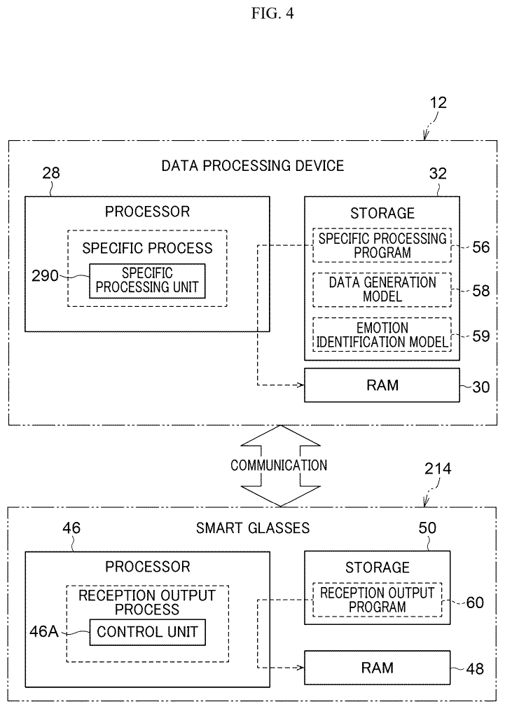

FIG. 4 illustrates an example of relevant functions of the data processing device 12 and the smart glasses 214. As illustrated in FIG. 4, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290. The specific processing unit 290 uses the emotion identification model 59 to estimate an emotion of a user, and is able to perform the specific processing using the user emotion. In an emotion estimation function (emotion identification function) that uses the emotion identification model 59, various estimations, predictions, and the like are performed related to emotions of the user, include estimating and predicting the emotion of the user, however, there is no limitation to such examples. Moreover, estimation and prediction of emotion also includes, for example, analyzing (parsing) emotions and the like.

Reception and output processing is performed by the processor 46 in the smart glasses 214. A reception and output program 60 is stored in the storage 50. The processor 46 reads the reception and output program 60 from the storage 50 and in the RAM 48 executes the read reception and output program 60. The reception and output processing is implemented by the processor 46 operating as the control unit 46A according to the reception and output program 60 executed in the RAM 48. Note that a configuration may be adopted in which the smart glasses 214 include a data generation model and an emotion identification model similar to the data generation model 58 and the emotion identification model 59, and processing similar to the specific processing unit 290 is performed using these models.

Next, description follows regarding the specific processing by the specific processing unit 290 of the data processing device 12. The units of the system described below are implemented by the data processing device 12 and the smart glasses 214. In the following description the data processing device 12 is called a “server”, and the smart glasses 214 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the smart glasses 214. The control unit 46A in the smart glasses 214 outputs the specific processing result to the speaker 240. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative Als such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the smart glasses 214, the processing may be executed by a specific processing unit 290 of the data processing device 12 and a control unit 46A of the smart glasses 214. Moreover, the specific processing unit 290 of the data processing device 12 acquires and collects information needed for processing from the smart glasses 214 or from an external device or the like, and the smart glasses 214 acquires and collects information needed for processing from the data processing device 12 or from an external device or the like.

For example, the collection unit is implemented by the control unit 46A of the smart glasses 214 and/or by the specific processing unit 290 of the data processing device 12. For example, an acquisition unit acquires number-of-steps data using the camera 42 and/or the communication I/F 44 of the smart glasses 214, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 of the smart glasses 214 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the smart glasses 214.

### Third Exemplary Embodiment

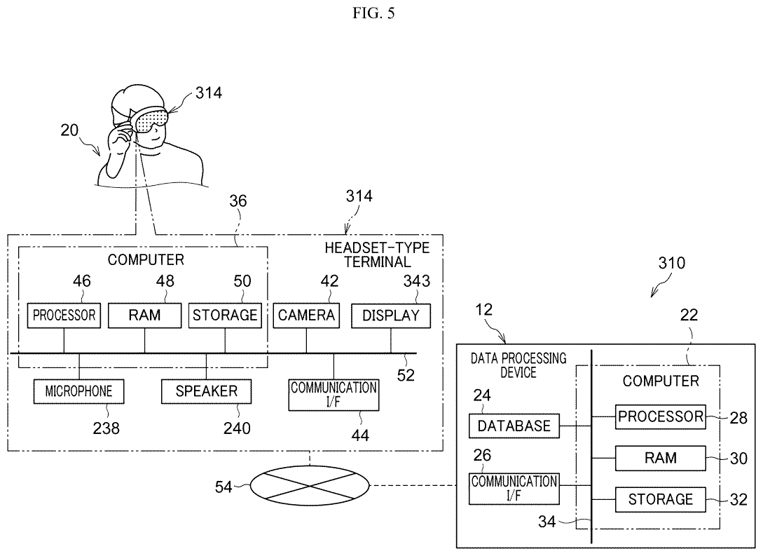

FIG. 5 illustrates an example of a configuration of a data processing system 310 according to a third exemplary embodiment.

As illustrated in FIG. 5, the data processing system 310 includes a data processing device 12 and a headset-type terminal 314. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The headset-type terminal 314 includes a computer 36, a microphone 238, a speaker 240, a camera 42, a communication I/F 44, and a display 343. The computer 36 includes a processor 46, RAM 48, and storage 50. The processor 46, the RAM 48, and the storage 50 are connected to a bus 52. The microphone 238, the speaker 240, the camera 42, the display 343, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the user 20 (for example, an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

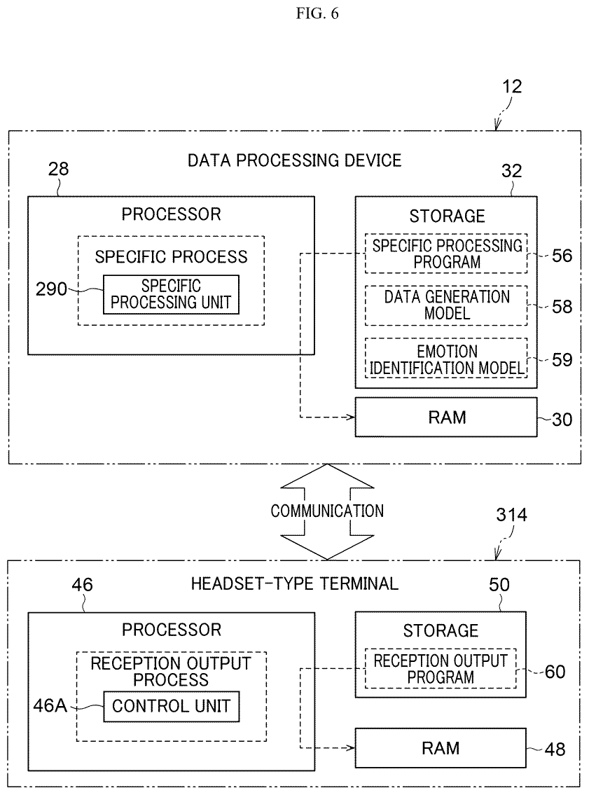

FIG. 6 illustrates an example of relevant functions of the data processing device 12 and the headset-type terminal 314. As illustrated in FIG. 6, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290.

Reception and output processing is performed by the processor 46 in the headset-type terminal 314. A reception and output program 60 is stored in the storage 50. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48.

Next, description follows regarding the specific processing by the specific processing unit 290 of the data processing device 12. The units of the system described below are implemented by the data processing device 12 and the headset-type terminal 314. In the following description the data processing device 12 is called a “server”, and the headset-type terminal 314 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the headset-type terminal 314. In the headset-type terminal 314, the control unit 46A outputs the result of the specific processing to the speaker 240 and the display 343. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative AIs such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the headset-type terminal 314, the processing may be executed by a specific processing unit 290 of the data processing device 12 and a control unit 46A of the headset-type terminal 314. Moreover, the specific processing unit 290 of the data processing device 12 acquires and collects information needed for processing from the headset-type terminal 314 or from an external device or the like, and the headset-type terminal 314 acquires and collects information needed for processing from the data processing device 12 or from an external device or the like.

For example, the collection unit is implemented by the control unit 46A of the headset-type terminal 314 and/or by the specific processing unit 290 of the data processing device 12. For example, an acquisition unit acquires number-of-steps data using the camera 42 and/or the communication I/F 44 of the headset-type terminal 314, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 and the display 343 of the headset-type terminal 314 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the headset-type terminal 314.

### Fourth Exemplary Embodiment

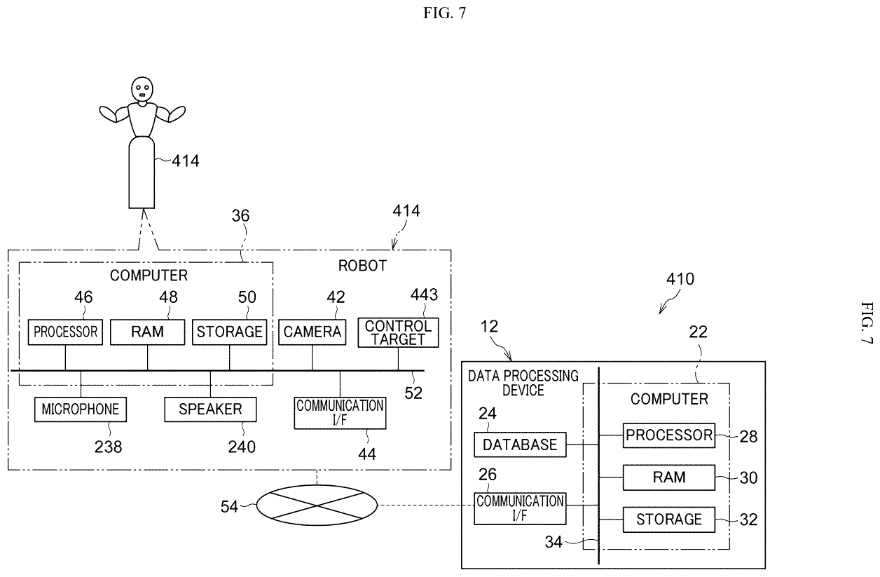

FIG. 7 illustrates an example of a configuration of a data processing system 410 according to a fourth exemplary embodiment

As illustrated in FIG. 7, the data processing system 410 includes a data processing device 12 and a robot 414. A server is an example of the data processing device 12.

The data processing device 12 includes a computer 22, a database 24, and a communication I/F 26. The computer 22 is an example of a “computer” according to technology disclosed herein. The computer 22 includes a processor 28, RAM 30, and storage 32. The processor 28, the RAM 30, and the storage 32 are connected to a bus 34. The database 24 and the communication I/F 26 are also connected to the bus 34. The communication I/F 26 is connected to a network 54. Examples of the network 54 include a Wide Area Network (WAN) and/or a local area network (LAN).

The robot 414 includes a computer 36, a microphone 238, a speaker 240, a camera 42, a communication I/F 44, and a control target 443. The computer 36 includes a processor 46, RAM 48, and storage 50. The processor 46, the RAM 48, and the storage 50 are connected to a bus 52. The microphone 238, the speaker 240, the camera 42, the control target 443, and the communication I/F 44 are also connected to the bus 52.

The microphone 238 receives an instruction or the like from a user 20 by receiving speech uttered by the user 20. The microphone 238 captures the speech uttered by the user 20, converts the captured speech into audio data, and outputs the audio data to the processor 46. The speaker 240 outputs audio under instruction from the processor 46.

The camera 42 is a compact digital camera installed with an optical system such as a lens, an aperture, a shutter, and the like, and with an imaging device such as a complementary metal-oxide semiconductor (CMOS) image sensor or a charge coupled device (CCD) image sensor or the like. The camera 42 images the surroundings of the robot 414 (for example, with an imaging range defined by an angle of view equivalent to the width of visual field of an ordinary healthy subject).

The communication I/F 44 is connected to the network 54. The communication I/F 44 and the communication I/F 26 perform the role of exchanging various information between the processor 46 and the processor 28 over the network 54. The exchange of various information between the processor 46 and the processor 28 is performed in a secure state using the communication I/F 44 and the communication I/F 26.

The control target 443 includes a display device, eye LEDs, and motors to drive arms, hands, feet, and the like. The posture and gesture of the robot 414 are controlled by controlling the motors of the arms, hands, feet, and the like. Part of an emotion of the robot 414 can be expressed by controlling these motors. Moreover, a facial expression of the robot 414 can be represented by controlling an illumination state of the eye LEDs of the robot 414.

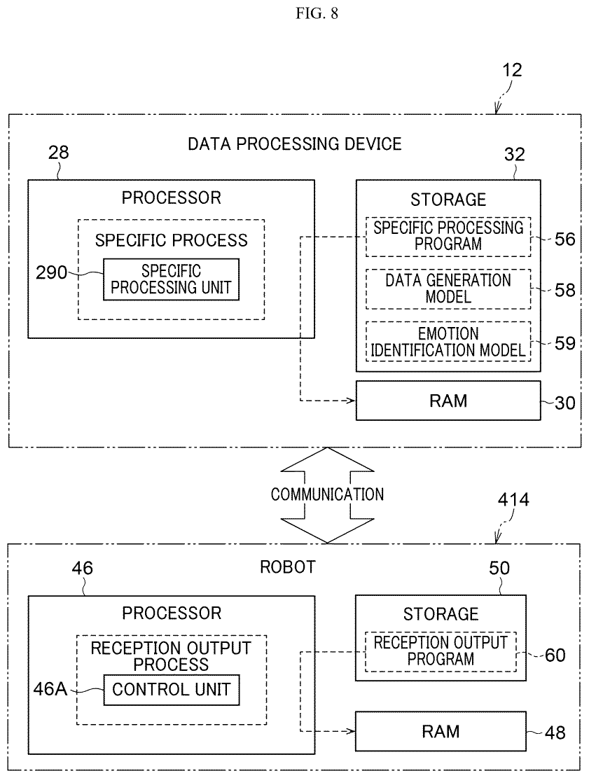

FIG. 8 illustrates an example of relevant functions of the data processing device 12 and the robot 414. As illustrated in FIG. 8, specific processing is performed by the processor 28 in the data processing device 12. A specific processing program 56 is stored in the storage 32.

The specific processing program 56 is an example of a “program” according to technology disclosed herein. The processor 28 reads the specific processing program 56 from the storage 32, and in the RAM 30 executes the read specific processing program 56. The specific processing is implemented by the processor 28 operating as the specific processing unit 290 according to the specific processing program 56 executed in the RAM 30.

The data generation model 58 and the emotion identification model 59 are stored in the storage 32. The data generation model 58 and the emotion identification model 59 are employed by the specific processing unit 290.

Reception and output processing is performed by the processor 46 in the robot 414. A reception and output program 60 is stored in the storage 50. The processor 46 reads the reception and output program 60 from the storage 50, and in the RAM 48 executes the read reception and output program 60. The reception and output processing is implemented by the processor 46 operating as the control unit 46A according to the reception and output program 60 executed in the RAM 48.

Next, description follows regarding the specific processing by the specific processing unit 290 of the data processing device 12. The units of the system described below are implemented by the data processing device 12 and the robot 414. In the following description the data processing device 12 is called a “server”, and the robot 414 is called a “terminal”.

### Example 1

Explanation of flow will be omitted due to being similar to a flow of the specific processing in Example 1 as described in the first exemplary embodiment above.

### Application Example 1

Explanation of flow will be omitted due to being similar to a flow of the specific processing in Application Example 1 as described in the first exemplary embodiment above.

### Example 2

Explanation of flow will be omitted due to being similar to a flow of the specific processing in Example 2 as described in the first exemplary embodiment above.

### Application Example 2

Explanation of flow will be omitted due to being similar to a flow of the specific processing in Application Example 2 as described in the first exemplary embodiment above.

The specific processing unit 290 transmits a result of the specific processing to the robot 414. In the robot 414, the control unit 46A outputs the result of the specific processing to the speaker 240 and the control target 443. The microphone 238 acquires audio representing user input in response to the specific processing result. The control unit 46A transmits audio data representing the user input as acquired by the microphone 238 to the data processing device 12. The specific processing unit 290 in the data processing device 12 acquires the audio data.

The data generation model 58 is a so-called generative artificial intelligence (AI). Examples of the data generation model 58 include generative Als such as ChatGPT (registered trademark) (Internet search <URL: https://openai.com/blog/chatgpt>) and the like. The data generation model 58 is obtained by performing deep learning with a neural network. The data generation model 58 is input with a prompt including an instruction, and is input with inference data such as audio data representing speech, text data representing text, image data representing images (for example, still image data or video data), and the like. The data generation model 58 takes the input inference data, performs inference according to the instruction indicated in the prompt, and outputs an inference result in one or more data format from out of audio data, text data, image data, or the like. The data generation model 58 includes, for example, a text generative AI, an image generative AI, a multimodal generative AI, or the like. Reference here to inference indicates, for example, analysis, classification, prediction, and/or abstraction etc. The specific processing unit 290 performs the specific processing referred to above while using the data generation model 58. The data generation model 58 may be a model fine-tuned so as to output an inference result from a prompt not including an instruction, and in such cases the data generation model 58 is able to output an inference result from the prompt not including an instruction. There are plural types of the data generation model 58 included in the data processing device 12 or the like, and the data generation models 58 include an AI other than a generative AI. An AI other than a generative AI is, for example, a linear regression, a logistic regression, a decision tree, a random forest, a support vector machine (SVM), a k-means clustering, a convolutional neural network (CNN), a recurrent neural network (RNN), a generative adversarial network (GAN), a naïve Bayes, or the like and is capable of performing various processing, however there is no limitation to such examples. The AI may be an AI agent. Moreover, when the processing of each of the units mentioned above is performed by an AI, this processing is partly or entirely performed by the AI, however there is no limitation to such examples. Moreover, processing executed by an AI including a generative AI may be switched to rule-based processing, and rule-based processing may be switched to processing executed by an AI including a generative AI.

Although the processing by the data processing system 10 described above is executed by the specific processing unit 290 of the data processing device 12 or by the control unit 46A of the robot 414, the processing may be executed by a specific processing unit 290 of the data processing device 12 and a control unit 46A of the robot 414. Moreover, the specific processing unit 290 of the data processing device 12 acquires and collects information needed for processing from the robot 414 or from an external device or the like, and the robot 414 acquires and collects information needed for processing from the data processing device 12 or from an external device or the like.

For example, the collection unit is implemented by the control unit 46A of the robot 414 and/or by the specific processing unit 290 of the data processing device 12. For example, an acquisition unit acquires number-of-steps data using the camera 42 and/or the communication I/F 44 of the robot 414, and the number-of-steps data is processed by the specific processing unit 290 of the data processing device 12. For example, an analysis unit implemented by the specific processing unit 290 of the data processing device 12 analyzes data from the collection unit and the acquisition unit. For example, a generation unit implemented by the specific processing unit 290 of the data processing device 12 generates a cooking menu using a generative AI. For example, a supply unit implemented by the speaker 240 and the control target 443 of the robot 414 and/or the specific processing unit 290 of the data processing device 12 supplies the generated cooking menu to the user. Correspondence relationships of each unit to devices and control units are not limited to the examples described above, and various modifications thereof are possible.

The above exemplary embodiment gives an implementation example in which the specific processing is performed by the data processing device 12, however technology disclosed herein is not limited thereto, and the specific processing may be performed by the robot 414.

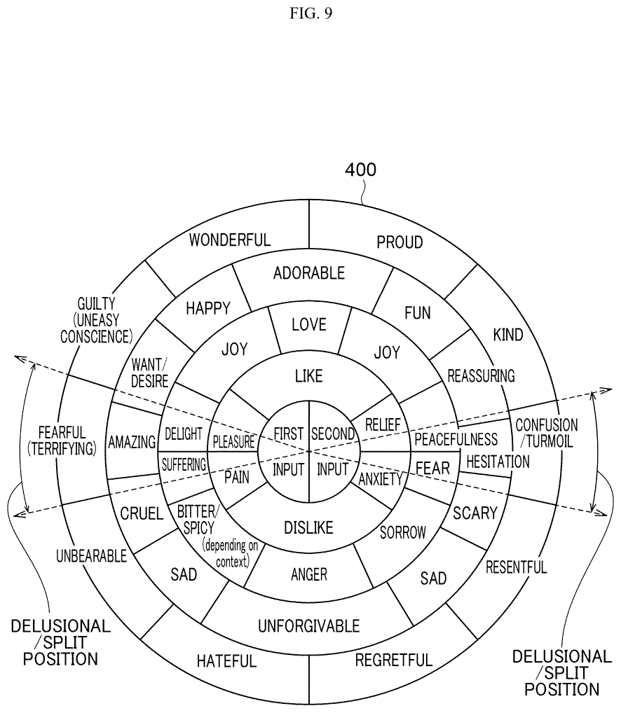

Note that the emotion identification model 59 serves as an emotion engine, and may decide the emotion of a user according to a specific mapping. Specifically, the emotion identification model 59 may decide the emotion of a user according to an emotion map (see FIG. 9) that is a specific mapping. Moreover, the emotion identification model 59 may also decide the emotion of the robot similarly, and the specific processing unit 290 may be configured so as to perform the specific processing using the emotion of the robot.

FIG. 9 is a diagram illustrating an emotion map 400 mapping plural emotions. In the emotion map 400, emotions are arranged in concentric circles that radiate out from the center. Primitive states of emotion are arranged nearer to the center of the concentric circles. Emotions expressing states and actions generated from states of mind are arranged further toward the outside of the concentric circles. Emotions are defined as including both affect and mental states. Emotions generated from reactions occurring in the brain are generally arranged at the left side of the concentric circles. Emotions induced by situational assessment are generally arranged at the right side of the concentric circles. Emotions generated from reactions occurring in the brain that are also emotions induced by situational assessment are generally arranged toward the top and toward the bottom of the concentric circles. Moreover, emotions of “euphoria” are arranged at the upper side of the concentric circles, and emotions of “dysphoria” are arranged at the lower side of the concentric circles. Plural emotions are accordingly mapped in this manner in the emotion map 400 based on a structure giving rise to emotions, and emotions that readily occur at the same time are mapped close to each other.

An example of such emotions is a distribution of emotions in the direction of 3 o'clock on the emotion map 400, generally around a boundary between relief and anxiety. Situational awareness dominates over internal sensations in the right half of the emotion map 400, with an impression of calm.

The inside of the emotion map 400 represents feelings, and the outside of the emotion map 400 represents actions, and so emotions further toward the outside of the emotion map 400 are more visible (are expressed by actions).

Human emotions are based on various balances, such as posture and blood sugar value balances, with a state of dysphoria being exhibited when these balances are far from ideal and a state of euphoria being exhibited when these balances are near to ideal. Even in a robot, a car, a motorbike, or the like, emotions can be thought of as being based on various balances such as orientation and remaining battery balances, with a state called dysphoria being exhibited when these balances are far from ideal and a state called euphoria being exhibited when these balances are near to ideal. An emotion map may, for example, be generated based on the emotion map of Dr. Mitsuyoshi (PhD Dissertation https://ci.nii.ac.jp/naid/500000375379: “Research on the phonetic recognition of feelings and a system for emotional physiological brain signal analysis”, Tokushima University). Emotions belonging to an area called “reaction” where feeling dominates are arranged in the left half of the emotion map. Moreover, emotions belonging to an area called “situation” where situational awareness dominates are arranged in the right half of the emotion map.

There are two types of emotion that facilitate leaning in an emotion map. One is an emotion in the vicinity of the center of negative “penitence” and “reflection” on the situational side. In other words, sometimes a negative “emotion” such as “I don't want to feel this way ever again” and “I don't want to be chided again” is experienced in a robot. Another is a positive emotion in the area of “desire” on the reaction side. In other words, there are times when a positive feeling such as “desire more” and “want to know more” is experienced.

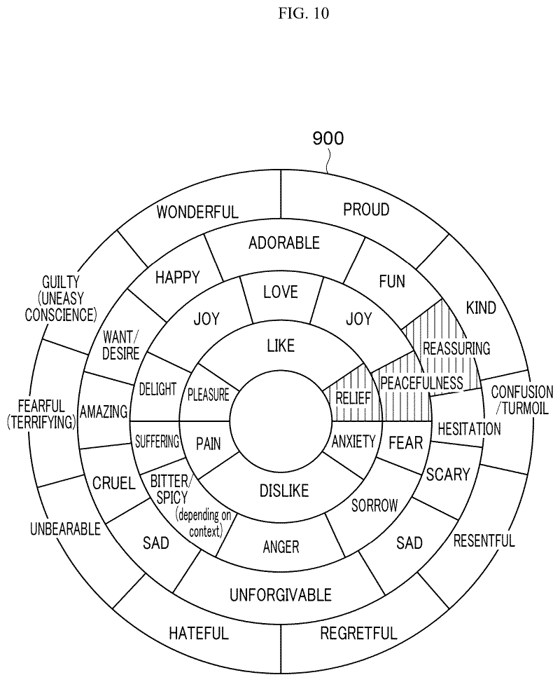

In the emotion identification model 59, user input is input to a pre-trained neural network, and emotion values indicating emotions shown on the emotion map 400 are acquired and the emotions of the user are decided. This neural network is pre-trained based on plural training data sets that each combine a user input with an emotion value indicating an emotion shown on the emotion map 400. The neural network is also trained such that emotions arranged close to each other have values that are close to each other, as in an emotion map 900 illustrated in FIG. 10. In FIG. 10 the plural emotions of “relief”, “peaceful”, and “reassured” are indicated as an example of close emotion values.

Although the system according to the present disclosure has been described mainly as functions of the data processing device 12, the system according to the present disclosure is not limited to being implemented in a server. The system according to the present disclosure may be implemented as a general information processing system. The present disclosure may, for example, be implemented by a software program operating on a personal computer, and may be implemented by an application operating on a smartphone or the like. The method according to the present disclosure may also be supplied to a user in the form of Software as a Service (SaaS).

Although in the exemplary embodiments described above examples are given of embodiments in which the specific processing is performed by a single computer 22, technology disclosed herein is not limited thereto, and distributed processing may be performed for the specific processing, with the specific processing distributed across plural computers including the computer 22. For example, the data generation model 58 may be provided in a device external to the data processing device 12, such that data generation in response to input data is performed in the external device.

Although in the exemplary embodiments described above examples are described of embodiments in which the specific processing program 56 is stored in the storage 32, the technology disclosed herein is not limited thereto. For example, the specific processing program 56 may be stored on a portable, non-transitory, computer readable, storage medium, such as universal serial bus (USB) memory or the like. The specific processing program 56 stored on the non-transitory storage medium is then installed on the computer 22 of the data processing device 12. The processor 28 then executes the specific processing according to the specific processing program 56.

Moreover, the specific processing program 56 may be stored on a storage device, such as a server connected to the data processing device 12 over the network 54, with the specific processing program 56 then being downloaded in response to a request from the data processing device 12 and installed on the computer 22.

Note that there is no need to store the entire specific processing program 56 on the storage device, such as a server connected to the data processing device 12 over the network 54, or to store the entire specific processing program 56 on the storage 32, and part of the specific processing program 56 may be stored thereon.

Hardware resources for executing the specific processing may use various processors as listed below. Examples of processors include, for example, a CPU that is a general-purpose processor that functions as a hardware resource to execute the specific processing by executing software, namely a program. Moreover, the processor may, for example, be a dedicated electronic circuit that is a processor having a circuit configuration custom designed for executing the specific processing, such as a field-programmable gate array (FPGA), a programmable logic device (PLD), or an application specific integrated circuit (ASIC). Memory is inbuilt or connected to each of these processors, and the specific processing is executed by each of these processors using the memory.

The hardware resource that executes the specific processing may be configured from one of these various processors, or may be configured from a combination of two or more processors of the same or different type (for example, a combination of plural FPGAs, or a combination of a CPU and a FPGA). The hardware resource executing the specific processing may be a single processor.

Examples of configurations of a single processor include, firstly, a configuration of a single processor resulting from combining one or more CPU and software, in an embodiment in which this processor functions as the hardware resource for executing the specific processing. Secondly, as typified by a System-on-chip (SOC) or the like, there is also an embodiment that uses a processor realized by a single IC chip to function as an overall system including plural hardware resources for executing the specific processing. Adopting such an approach means that the specific processing is realized using one or more of the various processors described above as hardware resource.

Furthermore, more specifically, an electrical circuit that combines circuit elements such as semiconductor elements or the like may be employed as a hardware structure of these various processors. The specific processing is merely an example thereof. This means that obviously redundant steps may be omitted, new steps may be added, and the processing sequence may be swapped around within a range not departing from the spirit of the present disclosure.

The described content and drawing content illustrated above are a detailed description of parts according to the present disclosure, and are merely examples of the present disclosure. For example, description related to the above configuration, function, operation, and advantageous effects is a description related to examples of the configuration, function, operation, and advantageous effects of parts according to the present disclosure. This means that obviously redundant parts may be eliminated, new elements may be added, and switching around may be performed on the described content and drawing content illustrated above within a range not departing from the spirit of the present disclosure. Moreover, to avoid misunderstanding and to facilitate understanding of parts according to the present disclosure, description related to common knowledge in the art and the like not particularly needing description to enable implementation of the present disclosure is omitted in the described content and drawing content illustrated as described above.

All publications, patent applications and technical standards mentioned in the present specification are incorporated by reference in the present specification to the same extent as if each individual publication, patent application, or technical standard was specifically and individually indicated to be incorporated by reference.

Note that, regarding the above description, the following supplementary notes are further disclosed.

### Example 1

### Supplementary 1

A system comprising a processor,
wherein the processor is configured to
receive electronic document data from an information terminal operated by a user, and extract design-related information, specification-related information, and configuration-related information from the electronic document data; and
perform preprocessing on the extracted information by using a natural language processing algorithm, the preprocessing including at least sentence segmentation, word segmentation, removal of non-informative content, and attachment of structural annotations, and generate learning data based on the preprocessed information; and
fine-tune a generative AI model based on a large-scale language model by using the learning data, and generate a domain-specific model that acquires, as internal representations, design-related information, specification-related information, and configuration-related information regarding commercial equipment; and
receive inquiry information including a prompt sentence from the user, select, as context information, information regarding the commercial equipment relevant to the inquiry information from the preprocessed information, and generate input data for the domain-specific model by combining the prompt sentence and the context information; and execute inference processing by the domain-specific model based on the input data, and generate response information including a prediction result of an impact range at occurrence of an incident and a recovery procedure based on patterns learned from the learning data; and transmit the response information to the information terminal and support design work or incident-response work by causing the response information to be displayed on the information terminal.

### Supplementary 2

The system according to supplementary 1,
wherein the processor is configured to convert the preprocessed information and the inquiry information into token sequences, and perform the fine-tuning by adjusting weight parameters of the generative AI model using the token sequences.

### Supplementary 3

The system according to supplementary 1,
wherein the processor is configured, when the inquiry information includes a prompt sentence related to an incident scenario, to estimate a current impact range of an incident based on feature patterns extracted from data regarding past incidents and based on the design-related information, the specification-related information, and the configuration-related information regarding the commercial equipment, and to include, in the response information, a recovery procedure corresponding to the impact range as a stepwise procedure.

### Application Example 1

### Supplementary 1

A system comprising a processor,
wherein the processor is configured to
acquire design information, specification information, and configuration information related to industrial equipment, preprocess the information as document data, segment and structure the document data, and store the structured document data, and
generate distributed representations for the segmented document data, construct an index structure based on the distributed representations, and select document data having a high relevance according to a predetermined search condition or event information, and
generate a prompt sentence to be input to a generative artificial intelligence model, the prompt sentence being generated on the basis of the selected document data and instruction information including work content or accident content, and transmit the prompt sentence to the generative artificial intelligence model so as to cause the generative artificial intelligence model to execute analysis processing, and
generate, on the basis of an analysis result output from the generative artificial intelligence model, work procedure information or recovery procedure information for the industrial equipment as structured instruction data, and distribute the instruction data to an output terminal, and
collect work execution status information and feedback information acquired from the output terminal, update contents of the work procedure information or the recovery procedure information on the basis of the work execution status information and the feedback information, and reuse updated instruction data as additional learning data for the generative artificial intelligence model or as data for generating the prompt sentence, and
in response to occurrence of an accident, input the design information, the specification information, the configuration information, and past accident information to the generative artificial intelligence model, predict an impact range, and generate optimal recovery procedure information on the basis of the prediction result and past patterns, and present the work procedure information or the recovery procedure information to an operator in units of steps on the output terminal, and acquire progress information and completion information of the steps in accordance with input operations from the operator.

### Supplementary 2

The system according to supplementary 1,
wherein the processor is configured to
generate the prompt sentence to be input to the generative artificial intelligence model by combining explanation information including the selected document data with control information including an output format, constraint conditions, and safety check items, so as to cause the generative artificial intelligence model to output instruction data including numbered steps, inspection items, and safety cautions.

### Supplementary 3

The system according to supplementary 1,
wherein the processor is configured to
calculate, on the basis of the work execution status information and the feedback information acquired from the output terminal, evaluation indices including work time, error occurrence frequency, and step-by-step performance indices, and automatically adjust contents of the prompt sentence for the generative artificial intelligence model or learning data for the generative artificial intelligence model in accordance with the evaluation indices.

### Example 2

### Supplementary 1

A system comprising a processor,
wherein the processor is configured to
learn design information, specification information, and configuration information of industrial facilities by performing additional training on a large-scale language model having a scale comparable to a generative AI model,
receive accident information transmitted from a user terminal by using a secure communication method, and normalize the accident information as structured data including time information, location information, impact range information, and failure content information,
generate a prompt sentence for input to the large-scale language model based on the normalized accident information, and generate an internal prompt sentence by adding context information including system configuration information and version information to the prompt sentence,
transmit the internal prompt sentence together with parameter information to the generative AI model, and acquire an analysis result text from the generative AI model, the analysis result text including design information, specification summary information, and component information related to the accident information,
analyze the analysis result text to extract related functional elements, connection relationships, and setting items, and generate structured design information including area information, document reference information, and countermeasure candidate information based on the extracted result,
acquire reference information of related design documents and drawings from a document management device or an information retrieval device based on the structured design information, and generate accident-response design information by adding the reference information to the structured design information,
format the accident-response design information into a predetermined display format, transmit the accident-response design information to the user terminal, and support identification of an accident cause and planning of a countermeasure policy by users of a plurality of departments,
analyze past accident data by using the generative AI model, estimate an impact range in a current accident, and present recovery procedure candidates based on patterns learned from the past accident data,
and analyze an emotional state of a user based on input content or operation history acquired from the user, and adjust a level of detail or an expression format of the design information to be presented according to the emotional state.

### Supplementary 2

The system according to supplementary 1,
wherein the processor is configured to
associate the internal prompt sentence with the analysis result text at a time of transmission of the internal prompt sentence to the generative AI model and acquisition of the analysis result text, record the association, and execute a learning process for updating a generation rule of the prompt sentence or a generation process of the structured design information based on the record.

### Supplementary 3

The system according to supplementary 1,
wherein the processor is configured to
control the user terminal to divide the accident-response design information received from an information processing device into a plurality of display regions including summary information, related functional element information, design drawing reference information, and investigation recommendation information, display the plurality of display regions, and, in response to a selection operation by the user on each display region, request a corresponding design document or drawing from an external information providing device.

### Application Example 2

### Supplementary 1

A system comprising a processor,
wherein the processor is configured to
preprocess and fine-tune a generative AI model based on a large language model that is comparable to generative artificial intelligence, by using document data including design information, specification information, configuration information, and incident information, and to cause the generative AI model to learn such information,
receive, when an incident occurs, numerical data and image data acquired from a detection mechanism and text data including an event description by a user, and generate composite feature data from the numerical data, the image data, and the text data by performing time-series alignment, missing-value completion, normalization, feature extraction, and integration,
estimate an impact range and candidate causes based on the composite feature data and a prediction model that has been learned on the basis of past events,
generate a prompt sentence to be input to the generative AI model on the basis of the impact range, the candidate causes, and context including the design information, the specification information, and the configuration information, and cause the generative AI model to generate, based on the prompt sentence, a natural-language response including an explanation of the incident and recovery procedures,
analyze an emotional state of the user on the basis of voice data, image data, or operation data of the user, and adjust at least one of a level of detail, an expression style, and a presentation method of the prompt sentence and the natural-language response in accordance with the emotional state,
perform presentation in which the impact range is visualized on at least one of a map and a facility layout and the recovery procedures are presented in a stepwise format, by using at least one of a display device and an audio output device, on the basis of the natural-language response and information indicating the impact range, and accept additional input from the user as a further prompt sentence and repeatedly cause the generative AI model to generate a further response, and
record, as a history, incident data, the composite feature data, prediction results, the prompt sentence, the natural-language response, and feedback from the user, and perform relearning or updating of the generative AI model and the prediction model on the basis of the history.

### Supplementary 2

The system according to supplementary 1,
wherein the processor is configured to insert metadata including the impact range, the candidate causes, target structural elements, and safety rules into the prompt sentence in the generation of the prompt sentence, and to parse the natural-language response obtained from the generative AI model to extract structured data indicating at least one of step numbers of the recovery procedures, target regions, and risk levels.

### Supplementary 3

The system according to supplementary 1,
wherein the processor is configured to append control information to the prompt sentence for the generative AI model on the basis of an emotion analysis result, the control information instructing at least one of performing a detailed explanation, performing a concise summary, and using expressions that reduce psychological load, and to dynamically change contents and a presentation mode of the recovery procedures by using the natural-language response generated in accordance with the control information.

What is claimed is:

1. A system comprising:
circuitry configured to:
receive electronic document data from an information terminal via a communication interface coupled to a packet-switched network, and extract design-related information, specification-related information, and configuration-related information from the electronic document data;
perform preprocessing on the extracted information using a natural language processing algorithm, the preprocessing comprising at least sentence segmentation, word segmentation, removal of non-informative content, and attachment of structural annotations, and generate learning data based on the preprocessed information;
fine-tune a generative AI model based on a large-scale language model using the learning data, and generate a domain-specific model that acquires, as internal representations, the design-related information, the specification-related information, and the configuration-related information regarding industrial equipment;
receive inquiry information comprising a prompt sentence from the information terminal, select, as context information, preprocessed information relevant to the inquiry information, generate input data by combining the prompt sentence and the context information, execute inference processing by the domain-specific model based on the input data, and generate response information comprising a prediction result of an impact range at occurrence of an incident and a recovery procedure based on patterns learned from the learning data; and
transmit the response information to the information terminal via the communication interface.

2. The system according to claim 1, wherein the circuitry is configured to
convert the preprocessed information and the inquiry information into token sequences, and perform the fine-tuning by adjusting weight parameters of the generative AI model using the token sequences.

3. The system according to claim 2, wherein the circuitry is configured to
apply a masked language modeling objective to the token sequences during fine-tuning to train the domain-specific model to generate context-aware outputs conditioned on the design-related information and configuration-related information.

4. The system according to claim 3, wherein the circuitry is configured to
store the token sequences and corresponding weight parameters in a memory after fine-tuning, and retrieve the stored weight parameters to initialize the domain-specific model for inference processing.

5. The system according to claim 4, wherein the circuitry is configured to
collect work execution status information and feedback information from the information terminal, update the recovery procedure based on the work execution status information and the feedback information, and reuse the updated recovery procedure as additional learning data for retraining the domain-specific model.

6. The system according to claim 1, wherein the circuitry is configured to
construct an index structure based on distributed representations generated for the preprocessed information, and select the context information by querying the index structure according to the inquiry information to retrieve preprocessed information having a high relevance score.

7. The system according to claim 6, wherein the distributed representations are generated by applying the domain-specific model as an encoder to segments of the preprocessed information, and the index structure is updated when new electronic document data is received.

8. The system according to claim 1, wherein the circuitry is configured to
when the inquiry information comprises a prompt sentence related to an incident scenario, estimate a current impact range of an incident based on feature patterns extracted from data regarding past incidents and based on the design-related information, the specification-related information, and the configuration-related information, and include in the response information a recovery procedure corresponding to the impact range as a stepwise procedure.

9. The system according to claim 8, wherein the circuitry is configured to
present the stepwise recovery procedure to an operator on the information terminal in units of steps, and acquire progress information and completion information of each step in accordance with input operations from the operator.

10. The system according to claim 9, wherein the circuitry is configured to
update the predicted impact range in response to the progress information received from the operator, and regenerate the recovery procedure based on the updated impact range.

11. The system according to claim 1, wherein the preprocessing further comprises applying a morphological analysis to the extracted information to generate normalized token representations, and applying structural annotations to identify sentence boundaries, headings, and enumerated items in the electronic document data.

12. The system according to claim 1, wherein the circuitry is configured to
analyze an emotional state of a user based on at least one of text input, interaction behavior signals, or sensor signals received from the information terminal, and adjust at least one of a detail level, a guidance level, and a presentation format of the response information based on the analyzed emotional state.

13. The system according to claim 12, wherein the circuitry is configured to
apply a trained sentiment classification model to the input signals to generate an emotional state label, and modify the prompt sentence supplied to the domain-specific model by appending an emotion-conditioned instruction based on the emotional state label.

14. The system according to claim 1, wherein the design-related information comprises component arrangements, system architecture, and design parameters extracted from the electronic document data, the specification-related information comprises performance conditions, operating constraints, and functional requirements, and the configuration-related information comprises interconnections, dependencies, and deployment settings of the industrial equipment.

15. The system according to claim 1, wherein the circuitry is configured to
generate a prompt sentence for input to the domain-specific model by combining selected document data with instruction information comprising work content or incident content, and cause the domain-specific model to execute analysis processing to generate work procedure information or recovery procedure information as structured instruction data.

16. The system according to claim 15, wherein the structured instruction data is formatted as a sequential list of steps with associated resource identifiers and time estimates, and is transmitted to the information terminal for display via the communication interface.

17. The system according to claim 1, wherein the circuitry is configured to
periodically receive updated electronic document data from the information terminal, extract updated design-related information, specification-related information, and configuration-related information, perform incremental fine-tuning of the domain-specific model using the updated learning data, and store the updated model weights in the memory.

18. A system comprising:
circuitry configured to:
extract design-related information, specification-related information, and configuration-related information from electronic document data received from an information terminal, and perform preprocessing comprising sentence segmentation, word segmentation, and structural annotation to generate learning data;
fine-tune a generative AI model using the learning data to generate a domain-specific model encoding internal representations of the industrial equipment information;
receive inquiry information comprising a prompt sentence, select context information from the preprocessed information based on the inquiry information, and execute inference processing by the domain-specific model to generate response information comprising an impact range prediction and a recovery procedure; and
transmit the response information to the information terminal, and analyze an emotional state of the user to adjust the detail level and presentation format of the response information.

19. The system according to claim 18, wherein the circuitry is configured to collect work execution status information and feedback information from the information terminal, and reuse the updated recovery procedure as additional learning data for incrementally retraining the domain-specific model.

20. A method comprising:
receiving electronic document data from an information terminal via a communication interface coupled to a packet-switched network, and extracting design-related information, specification-related information, and configuration-related information from the electronic document data;
performing preprocessing on the extracted information using a natural language processing algorithm, the preprocessing comprising at least sentence segmentation, word segmentation, removal of non-informative content, and attachment of structural annotations, and generating learning data based on the preprocessed information;
fine-tuning a generative AI model based on a large-scale language model using the learning data, and generating a domain-specific model that acquires, as internal representations, the design-related information, the specification-related information, and the configuration-related information regarding industrial equipment;
receiving inquiry information comprising a prompt sentence from the information terminal, selecting, as context information, preprocessed information relevant to the inquiry information, generating input data by combining the prompt sentence and the context information, executing inference processing by the domain-specific model based on the input data, and generating response information comprising a prediction result of an impact range at occurrence of an incident and a recovery procedure based on patterns learned from the learning data; and
transmitting the response information to the information terminal via the communication interface.
